(19) United States
(12) Patent Application Publication
(10) Pub. No.: US 2025/0072225 A1
(43) Pub. Date: Feb. 27, 2025

(54) DISPLAY SUBSTRATE, DISPLAY PANEL, AND DISPLAY APPARATUS

(71) Applicants: Chengdu BOE Optoelectronics Technology Co., Ltd., Chengdu (CN); BOE Technology Group Co., Ltd., Beijing (CN)

(72) Inventors: Yu Wu, Beijing (CN); Yipeng Chen, Beijing (CN); Haoyu Li, Beijing (CN); Yuxiao Li, Beijing (CN)

(21) Appl. No.: 18/693,236

(22) PCT Filed: Aug. 22, 2023
(86) PCT No.: PCT/CN2023/114192

§ 371 Date: Mar. 19, 2024

(51) Int. Cl. H10K 59/122; H10K 59/80

(52) U.S. Cl. CPC H10K 59/122; H10K 59/873

(57) ABSTRACT

The present disclosure provides a display substrate. A partition structure is provided between two sub-pixels adjacent to each other, and includes a partition portion and a first groove, and an orthographic projection of the partition portion overlaps partially with an orthographic projection of the first groove. The sub-pixel includes an organic light-emitting device, which includes a charge generation portion. For two adjacent sub-pixels and the partition structure therebetweeen, the charge generation portion of one includes a first extension sub-portion extending between the two sub-pixels, and the charge generation portion of the other includes a second extension sub-portion extending between the two sub-pixels that are insulated and spaced apart from the first extension sub-portion. One of the first extension sub-portion and the second extension sub-portion is on a side of the partition portion away from the base substrate, the other is on a bottom wall of the first groove.

### CROSS-REFERENCE TO RELATED APPLICATION

This application is a Section 371 National Stage Application of International Application No. PCT/CN2023/114192, filed Aug. 22, 2023, entitled “DISPLAY SUBSTRATE, DISPLAY PANEL, AND DISPLAY APPARATUS”, the content of which is incorporated herein by reference in its entirety.

### TECHNICAL FIELD

The present disclosure relates to a field of display technology, and specifically to a display substrate, a display panel, and a display apparatus.

### BACKGROUND

At present, display screens mainly include liquid crystal display (LCD) screens and organic light-emitting diode (OLED) display screens. A liquid crystal display screen typically includes a display substrate, a counter substrate arranged opposite to the display substrate, and a liquid crystal layer between the display substrate and the opposed substrate. The liquid crystal display screen may generate an electric field through pixel electrodes in the display substrate to change a rotation direction of liquid crystal molecules in the liquid crystal layer, and display using polarizers. An organic light-emitting diode display screen includes an anode, a cathode, and a light-emitting portion arranged between the anode and the cathode. The organic light-emitting diode may generate a current through the anode and the cathode to drive the light-emitting portion to emit light for display.

With a development of display technology, higher requirements are put forward for light of sub-pixels. Higher light corresponds to a greater current, then a current between two sub-pixels adjacent to each other may generate a crosstalk.

### SUMMARY

In view of the above problems, the present disclosure provides a display substrate, a display panel, and a display apparatus.

According to a first aspect of the present disclosure, a display substrate is provided, including:
a base substrate;
a first planarization layer provided on the base substrate;
a first passivation layer provided on a side of the first planarization layer away from the base substrate; and
an organic light-emitting layer and an organic common layer, where the organic light-emitting layer and the organic common layer are provided on a side of the first passivation layer away from the base substrate,
where the display substrate further includes a plurality of sub-pixels, a partition structure is provided between two sub-pixels adjacent to each other, the partition structure includes a partition portion in the first passivation layer and a first groove in the first planarization layer, and an orthographic projection of the partition portion on the base substrate partially overlaps with an orthographic projection of the first groove on the base substrate,
where at least one sub-pixel includes an organic light-emitting device, and the organic light-emitting device includes a light-emitting portion in the organic light-emitting layer and a charge generation portion in the organic common layer;
where for two sub-pixels adjacent to each other and the partition structure between the two sub-pixels adjacent to each other, the charge generation portion of one sub-pixel includes a first extension sub-portion extending between the two sub-pixels adjacent to each other, and the charge generation portion of the other sub-pixel includes a second extension sub-portion extending between the two sub-pixels adjacent to each other; and
where one of the first extension sub-portion and the second extension sub-portion is on a side of the partition portion away from the base substrate, the other of the first extension sub-portion and the second extension sub-portion is on a bottom wall of the first groove, and the first extension sub-portion and the second extension sub-portion are insulated and spaced apart from each other.

According to the embodiments of the present disclosure, the display substrate further includes a first electrode layer on a side of the organic light-emitting layer proximate to the base substrate, a second electrode layer on a side of the organic light-emitting layer away from the base substrate, and a pixel circuit layer on a side of the first planarization layer proximate to the base substrate;
where the at least one sub-pixel further includes a pixel circuit, the organic light-emitting device further includes a first electrode in the first electrode layer and a second electrode in the second electrode layer, the first electrode is electrically connected to the pixel circuit, and the second electrode is electrically connected to a first voltage terminal;
where for two sub-pixels adjacent to each other and the partition structure between the two sub-pixels adjacent to each other, the second electrode of one sub-pixel includes a third extension sub-portion extending between the two sub-pixels adjacent to each other, and the second electrode of the other sub-pixel includes a fourth extension sub-portion extending between the two sub-pixels adjacent to each other; and
where the third extension sub-portion is on a side of the first extension sub-portion away from the base substrate, the fourth extension sub-portion is on a side of the second extension sub-portion away from the base substrate, and the third extension sub-portion and the fourth extension sub-portion are insulated and spaced apart from each other.

According to the embodiments of the present disclosure, the at least one sub-pixel further includes a first connecting portion, and in a same sub-pixel, the first electrode is electrically connected to the pixel circuit through the first connecting portion; and
where the orthographic projection of the first groove on the base substrate does not overlap with an orthographic projection of the first connecting portion on the base substrate.

According to the embodiments of the present disclosure, the partition portion includes a first partition sub-portion and a second partition sub-portion; and
where the first partition sub-portion covers a surface of the first planarization layer on a side away from the base substrate, the orthographic projection of the first groove on the base substrate covers an orthographic projection of the second partition sub-portion on the base substrate, and an orthographic projection of the first partition sub-portion on the base substrate at least partially surrounds the orthographic projection of the second partition sub-portion on the base substrate.

According to the embodiments of the present disclosure, for two sub-pixels adjacent to each other and the partition structure between the two sub-pixels adjacent to each other,
in a direction from one sub-pixel to the other sub-pixel, a spacing between the first groove and one sub-pixel is less than a spacing between the first groove and the other sub-pixel,
where the first extension sub-portion of the one sub-pixel having a less spacing from the first groove than the other sub-pixel is on the side of the partition portion away from the base substrate, and the second extension sub-portion of the other sub-pixel having a greater spacing from the first groove than the one sub-pixel is on the bottom wall of the first groove.

According to the embodiments of the present disclosure, the at least one sub-pixel further includes a first passivation portion in the first passivation layer, and in a same sub-pixel, an orthographic projection of the first passivation portion on the base substrate covers an orthographic projection of the first electrode on the base substrate; and
where for two sub-pixels adjacent to each other and the partition structure between the two sub-pixels adjacent to each other, the first passivation portion of one sub-pixel and the partition portion are formed as an integral structure.

According to the embodiments of the present disclosure, the display substrate further includes a first pixel defining layer on a side of the first electrode layer away from the base substrate and a second pixel defining layer between the first pixel defining layer and the first passivation layer, a material of the first pixel defining layer includes a black pixel defining material, and a material of the second pixel defining layer includes a transparent pixel defining material;
where the at least one sub-pixel further includes a pixel defining portion in the first pixel defining layer and an auxiliary attaching portion in the second pixel defining layer; and
where in a same sub-pixel, the pixel defining portion is configured to define an effective light-emitting region of the organic light-emitting device, the pixel defining portion is attached to the first passivation portion through the auxiliary attaching portion, and a maximum thickness of the auxiliary attaching portion is less than or equal to a maximum thickness of the pixel defining portion.

According to the embodiments of the present disclosure, in a same sub-pixel, an orthographic projection of the pixel defining portion on the base substrate overlaps with the orthographic projection of the first passivation portion on the base substrate, and an overlap between the orthographic projection of the pixel defining portion on the base substrate and the orthographic projection of the first passivation portion on the base substrate defines a first pattern; and
where the first pattern includes a middle region and an edge region outside the middle region, the orthographic projection of the first electrode on the base substrate covers the middle region, and an orthographic projection of the auxiliary attaching portion on the base substrate covers the edge region.

According to the embodiments of the present disclosure, in a same sub-pixel, an orthographic projection of the auxiliary attaching portion on the base substrate surrounds the orthographic projection of the first electrode on the base substrate.

According to the embodiments of the present disclosure, for two sub-pixels adjacent to each other and the partition structure between the two sub-pixels adjacent to each other, an orthographic projection of the first electrode of at least one sub-pixel on the base substrate does not overlap with the orthographic projection of the partition portion on the base substrate.

According to the embodiments of the present disclosure, a plurality of partition structures are provided between two sub-pixels adjacent to each other, and at least two of the plurality of partition structures have different areas.

According to the embodiments of the present disclosure, the display substrate further includes a second planarization layer between the first passivation layer and the first electrode layer;
where the at least one sub-pixel further includes a first spacing portion in the second planarization layer; and
where in a same sub-pixel, the orthographic projection of the first electrode on the base substrate overlaps with the orthographic projection of the first passivation portion on the base substrate, an overlap between the orthographic projection of the first electrode on the base substrate and the orthographic projection of the first passivation portion on the base substrate defines a second pattern, and an orthographic projection of the first spacing portion on the base substrate covers the second pattern.

According to the embodiments of the present disclosure, in a same sub-pixel, an orthographic projection of the pixel defining portion on the base substrate overlaps with the orthographic projection of the first passivation portion on the base substrate, an overlap between the orthographic projection of the pixel defining portion on the base substrate and the orthographic projection of the first passivation portion on the base substrate defines a first pattern, and the orthographic projection of the first spacing portion on the base substrate covers the first pattern.

According to the embodiments of the present disclosure, the at least one sub-pixel further includes a first planarization portion in the first planarization layer; and
where in a same sub-pixel, a thickness of the first spacing portion is less than or equal to a thickness of the first passivation portion, and the thickness of the first passivation portion is less than a thickness of the first planarization portion.

According to the embodiments of the present disclosure, the plurality of sub-pixels include a first sub-pixel, a second sub-pixel, and a third sub-pixel, the first sub-pixel and the second sub-pixel have different colors, and the second sub-pixel has the same color as the third sub-pixel;
where for a first sub-pixel, a second sub-pixel adjacent to the first sub-pixel, and the partition structure between the first sub-pixel and the second sub-pixel, in a direction from the first sub-pixel to the second sub-pixel, a spacing between the first groove and the first sub-pixel is less than a spacing between the first groove and the second sub-pixel; and
where for a first sub-pixel, a third sub-pixel adjacent to the first sub-pixel, and the partition structure between the first sub-pixel and the third sub-pixel, in a direction from the first sub-pixel to the third sub-pixel, a spacing between the first groove and the first sub-pixel is less than a spacing between the first groove and the third sub-pixel.

According to the embodiments of the present disclosure, the orthographic projection of the partition structure adjacent to the first sub-pixel on the base substrate defines a third pattern at least partially surrounding an orthographic projection of a pixel opening of the first sub-pixel on the base substrate.

According to the embodiments of the present disclosure, the plurality of sub-pixels further include a fourth sub-pixel, and the first sub-pixel, the second sub-pixel and the fourth sub-pixel have different colors from each other;
where for a third sub-pixel, a fourth sub-pixel adjacent to the third sub-pixel, and the partition structure between the third sub-pixel and the fourth sub-pixel, in a direction from the third sub-pixel to the fourth sub-pixel, a spacing between the first groove and the third sub-pixel is less than a spacing between the first groove and the fourth sub-pixel; and
where for a second sub-pixel, a fourth sub-pixel adjacent to the second sub-pixel, and the partition structure between the second sub-pixel and the fourth sub-pixel, in a direction from the second sub-pixel to the fourth sub-pixel, a spacing between the first groove and the second sub-pixel is less than a spacing between the first groove and the fourth sub-pixel.

According to the embodiments of the present disclosure, an area of an effective light-emitting region of the first sub-pixel is greater than an area of an effective light-emitting region of the second sub-pixel and is less than an area of an effective light-emitting region of the fourth sub-pixel, and the area of the effective light-emitting region of the second sub-pixel is substantially equal to the area of the effective light-emitting region of the third sub-pixel.

According to the embodiments of the present disclosure, the display substrate further includes a plurality of gate lines extending in a first direction and a plurality of data lines extending in a second direction;
where first sub-pixels and second sub-pixels are alternately arranged in a third direction, the first sub-pixels and third sub-pixels are alternately arranged in a fourth direction, the third sub-pixels and fourth sub-pixels are alternately arranged in the third direction, and the second sub-pixels and the fourth sub-pixels are alternately arranged in the fourth direction; and
where the first direction, the second direction, the third direction and the fourth direction intersect with one another.

According to the embodiments of the present disclosure, the orthographic projection of the partition structure adjacent to the third sub-pixel in the third direction on the base substrate defines a fourth pattern at least partially surrounding an orthographic projection of a pixel opening of the third sub-pixel on the base substrate; and/or
where the orthographic projection of the partition structure adjacent to the second sub-pixel in the fourth direction on the base substrate defines a fifth pattern at least partially surrounding an orthographic projection of a pixel opening of the second sub-pixel on the base substrate.

According to a second aspect of the present disclosure, a display panel is provided, including the display substrate described above.

According to a third aspect of the present disclosure, a display apparatus is provided, including the display panel described above.

### BRIEF DESCRIPTION OF THE DRAWINGS

The above contents and other objectives, features and advantages of the present disclosure will be more apparent through the following descriptions of the embodiments of the present disclosure with reference to the accompanying drawings. In the accompanying drawings:

FIG. 1 schematically shows a top view of a display substrate according to an embodiment of the present disclosure;

FIG. 2 schematically shows a top view of sub-pixels according to an embodiment of the present disclosure;

FIG. 3 schematically shows a top view of sub-pixels and partition structures according to an embodiment of the present disclosure;

FIG. 4 schematically shows a cross-sectional view of sub-pixels and partition structures according to an embodiment of the present disclosure;

FIG. 5 schematically shows a first cross-sectional view of two sub-pixels adjacent to each other according to an embodiment of the present disclosure;

FIG. 6 schematically shows a cross-sectional view of a light-emitting device according to an embodiment of the present disclosure;

FIG. 7 schematically shows a second cross-sectional view of two sub-pixels adjacent to each other according to an embodiment of the present disclosure;

FIG. 8A schematically shows a first top view of a first passivation layer according to an embodiment of the present disclosure;

FIG. 8B schematically shows a top view of a first electrode layer according to an embodiment of the present disclosure;

FIG. 8C schematically shows a top view of a first pixel defining layer according to an embodiment of the present disclosure;

FIG. 8D schematically shows a top view of a first groove according to an embodiment of the present disclosure;

FIG. 9 schematically shows a first top view of a first passivation layer, a first electrode layer, a first pixel defining layer and a first groove according to an embodiment of the present disclosure;

FIG. 10A and FIG. 10B schematically show schematic diagrams of a spacing between a first groove and a sub-pixel according to an embodiment of the present disclosure;

FIG. 11 schematically shows a second top view of a first passivation layer according to an embodiment of the present disclosure;

FIG. 12 schematically shows a second top view of a first passivation layer, a first electrode layer, a first pixel defining layer and a first groove according to an embodiment of the present disclosure;

FIG. 13 schematically shows a third cross-sectional view of two sub-pixels adjacent to each other according to an embodiment of the present disclosure;

FIG. 14 schematically shows a top view of a second pixel defining layer according to an embodiment of the present disclosure;

FIG. 15 schematically shows a top view of a first passivation layer, a first electrode layer, a first pixel defining layer, a second pixel defining layer and a first groove according to an embodiment of the present disclosure;

FIG. 16 schematically shows a fourth cross-sectional view of two sub-pixels adjacent to each other according to an embodiment of the present disclosure;

FIG. 17 schematically shows a third top view of a first passivation layer according to an embodiment of the present disclosure;

FIG. 18 schematically shows a third top view of a first passivation layer, a first electrode layer, a first pixel defining layer and a first groove according to an embodiment of the present disclosure;

FIG. 19 schematically shows a fifth cross-sectional view of two sub-pixels adjacent to each other according to an embodiment of the present disclosure;

FIG. 20 schematically shows a top view of a second planarization layer according to an embodiment of the present disclosure;

FIG. 21 schematically shows a top view of a first passivation layer, a first electrode layer, a first pixel defining layer, a second planarization layer and a first groove according to an embodiment of the present disclosure; and

FIG. 22 schematically shows a sixth cross-sectional view of two sub-pixels adjacent to each other according to an embodiment of the present disclosure.

### DETAILED DESCRIPTION OF EMBODIMENTS

In order to make objectives, technical solutions and advantages of the embodiments of the present disclosure clearer, technical solutions of the embodiments of the present disclosure will be clearly and completely described below with reference to the accompanying drawings. Obviously, the described embodiments are just some embodiments rather than all embodiments of the present disclosure. Based on the described embodiments of the present disclosure, all additional embodiments obtained by those ordinary skilled in the art without carrying out inventive effort fall within the scope of protection of the present disclosure.

It will be noted that in the accompanying drawings, for clarity and/or description purposes, a size and relative size of an element may be enlarged. Accordingly, the size and relative size of each element are not necessarily limited to those shown in the figures. In the specification and the accompanying drawings, the same or similar reference numerals represent the same or similar components.

When an element is described as being “on”, “connected to” or “coupled to” another element, the element may be directly on the another element, directly connected to the another element, or directly coupled to the another element, or an intermediate element may be provided. However, when an element is described as being “directly on”, “directly connected to” or “directly coupled to” another element, no intermediate element is provided. Other terms and/or expressions used to describe a relationship between elements, such as “between” and “directly between”, “adjacent to” and “directly adjacent to”, “on” and “directly on”, and so on, should be interpreted in a similar manner. Moreover, the term “connection” may refer to a physical connection, an electrical connection, a communicative connection, and/or a fluid connection. In addition, X-axis, Y-axis and Z-axis are not limited to three axes of a rectangular coordinate system, and may be interpreted in a broader meaning. For example, the X-axis, the Y-axis and the Z-axis may be perpendicular to each other, or may represent different directions that are not perpendicular to each other. For objectives of the present disclosure, “at least one of X, Y or Z” and “at least one selected from a group consisting of X, Y and Z” may be interpreted as only X, only Y, only Z, or any combination of two or more of X, Y and Z, such as XYZ, XYY, YZ and ZZ. As used herein, the term “and/or” includes any and all combinations of one or more of the listed related items.

It will be noted that although the terms “first”, “second”, etc. may be used herein to describe various components, members, elements, regions, layers and/or portions, these components, members, elements, regions, layers and/or portions should not be limited by these terms. Rather, these terms are used to distinguish one component, member, element, region, layer and/or portion from another one. Thus, for example, a first component, a first member, a first element, a first region, a first layer and/or a first portion discussed below may be referred to as a second component, a second member, a second element, a second region, a second layer and/or a second portion without departing from teachings of the present disclosure.

For ease of description, spatial relationship terms, such as “upper”, “lower”, “left”, “right”, etc. may be used herein to describe a relationship between an element or feature and another element or feature as shown in the figures. It should be understood that the spatial relationship terms are intended to cover other different orientations of a device in use or operation in addition to the orientation described in the figures. For example, if a device in the figures is turned upside down, an element or feature described as “below” or “under” another element or feature will be oriented “above” or “on” the another element or feature.

Here, the terms “substantially”, “about”, “approximately” and other similar terms are used as terms of approximation rather than terms of degree, and they are intended to explain an inherent deviation of a measured or calculated value that will be recognized by those ordinary skilled in the art. Taking into account a process fluctuation, a measurement problem, an error related to a measurement of a specific quantity (that is, a limitation of a measurement system) and other factors, the terms “substantially”, “about” or “approximately” used herein includes a stated value and means that a specific value determined by those ordinary skilled in the art is within an acceptable range of deviation. For example, “about” may mean being within one or more standard deviations, or within ±30%, ±20%, ±10% or ±5% of the stated value.

It will be noted that the expression “the same layer” herein refers to a layer structure that is formed by firstly forming, using a same film forming process, a film layer used to form a specific pattern, and then patterning, using one-time patterning process, the film layer with a same mask. Depending on different specific patterns, the one-time patterning process may include a plurality of exposure, development or etching processes, and the specific pattern in the formed layer structure may be continuous or discontinuous. That is, a plurality of elements, components, structures and/or portions located in the “same layer” are made of the same material and formed by the same patterning process. Generally, a plurality of elements, components, structures and/or portions located in the “same layer” have substantially the same thickness.

Those skilled in the art should understand that, unless otherwise specified, the expression “height” or “thickness” herein refers to a size in a direction perpendicular to a surface of each film layer provided on the display substrate, that is, a size in a light-emitting direction of the display substrate, or called a size in a normal direction of the display apparatus.

In an example, a display substrate is provided, which includes a base substrate and a plurality of sub-pixels arranged on the base substrate. The sub-pixel includes an organic light-emitting device (e.g., Organic Light-Emitting Diode, OLED), and the organic light-emitting device includes a light-emitting portion, and a first electrode and a second electrode on opposite sides of the light-emitting portion. For example, the first electrode is on a side of the light-emitting portion proximate to the base substrate, and the second electrode is on a side of the light-emitting portion away from the base substrate. One of the first electrode and the second electrode is an anode, and the other is a cathode.

The organic light-emitting device further includes a charge generation portion. For example, the charge generation portion includes at least one of a hole transport layer, a hole injection layer, an electron transport layer, or an electron injection layer. The hole injection layer is on the side of the light-emitting portion proximate to the base substrate, the hole transport layer is between the light-emitting portion and the hole injection layer, the electron injection layer is on the side of the light-emitting portion away from the base substrate, and the electron transport layer is between the light-emitting portion and the electron injection layer. In sub-pixels adjacent to each other, a layer where the charge generation portions are located may be a continuous integral layer (this film layer may also be referred to as a common layer) formed through a single process, so that the process costs may be reduced.

With a development of the display technology, higher requirements are put forward for luminance of sub-pixels. Higher luminance corresponds to a greater current, which causes the current may be conducted between two sub-pixels adjacent to each other through the charge generation portions of the two sub-pixels adjacent to each other, thereby generating a crosstalk. For example, when a green sub-pixel is turned on, a red sub-pixel adjacent to the green sub-pixel may also be turned on abnormally due to a low turn-on voltage of the red sub-pixel, which may cause an obvious color shift in a picture. For example, there may be a phenomenon that a green picture shifts to red.

In view of this, the embodiments of the present disclosures provide a display substrate, which includes a base substrate, a first planarization layer provided on the base substrate, a first passivation layer provided on a side of the first planarization layer away from the base substrate, and an organic light-emitting layer and an organic common layer that are provided on a side of the first passivation layer away from the base substrate.

The display substrate further includes a plurality of sub-pixels, and a partition structure is provided between two sub-pixels adjacent to each other in a predetermined direction. The partition structure includes a partition portion and a first groove, the partition portion is located in the first passivation layer, and the first groove is located in the first planarization layer. An orthographic projection of the partition portion on the base substrate overlaps partially with an orthographic projection of the first groove on the base substrate. At least one sub-pixel includes an organic light-emitting device. The organic light-emitting device includes a light-emitting portion and a charge generation portion, the light-emitting portion is located in the organic light-emitting layer, and the charge generation portion is located in the organic common layer. For two sub-pixels adjacent to each other and the partition structure between the two sub-pixels adjacent to each other, the charge generation portion of one sub-pixel includes a first extension sub-portion extending between the two sub-pixels, and the charge generation portion of the other sub-pixel includes a second extension sub-portion extending between the two sub-pixels. One of the first extension sub-portion and the second extension sub-portion is on a side of the partition portion away from the base substrate, and the other is on a bottom wall of the first groove. The first extension sub-portion and the second extension sub-portion are insulated and spaced apart from each other.

With the partition structure, the charge generation portions of two sub-pixels adjacent to each other may be insulated and spaced apart without changing the preparation process of the charge generation portions, so as to prevent the current being conducted between the two sub-pixels through the charge generation portions, so that the problem such as crosstalk and color shift caused by this may be alleviated. Moreover, in the embodiments of the present disclosure, the partition portion partially covers the first groove to form an undercut structure. The first planarization layer has a large thickness, and forming a groove in the first planarization layer to form the undercut structure may not affect the existing structures. In addition, due to the large thickness of the first planarization layer, the first extension sub-portion and the second extension sub-portion may have a sufficient height difference, so as to ensure a misalignment of the two, thereby preventing a connection between the two caused by process fluctuations.

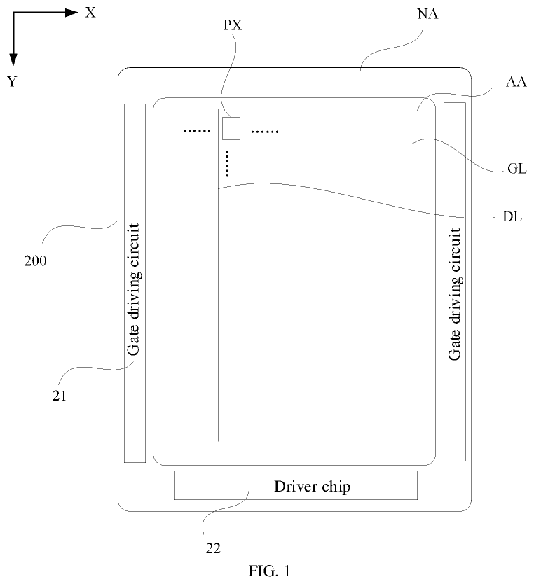

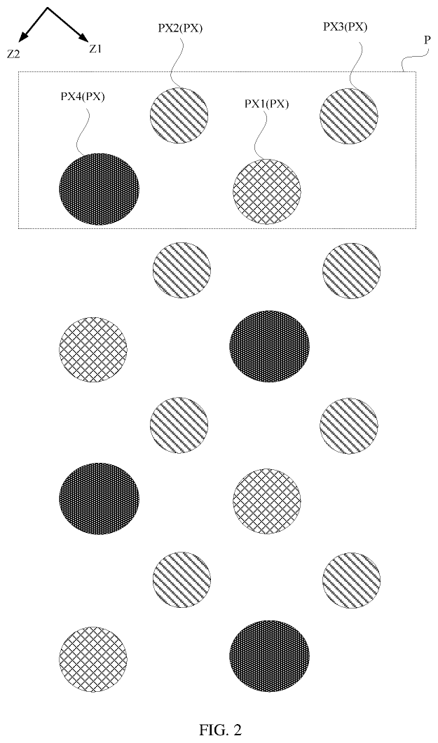

FIG. 1 schematically shows a top view of a display substrate according to the embodiments of the present disclosure. FIG. 2 schematically shows a top view of sub-pixels according to the embodiments of the present disclosure.

Referring to FIG. 1 and FIG. 2, the display substrate in the embodiments of the present disclosure includes a display area AA and a peripheral area NA on at least one side of the display area AA.

The display area AA may have various shapes. For example, the display area AA may be provided in various shapes such as a closed polygon including straight edges (e.g., a rectangle), a shape including a curved side such as a circle and an ellipse, and a shape including both a straight edge and a curved side such as a semicircle and a semi-ellipse. In the embodiments of the present disclosure, the display area AA is set as a region having a quadrangular shape including straight edges. It will be understood that this is just an exemplary embodiment of the present disclosure, rather than a limitation to the present disclosure.

The display substrate may further include a base substrate 200 and a plurality of repetitive units P provided on the base substrate 200 and located in the display area AA. Each repetitive unit P may include a plurality of sub-pixels PX. In a same repetitive unit P, at least two sub-pixels PX have different colors.

For example, the repetitive unit P may include a first sub-pixel PX1, a second sub-pixel PX2, a third sub-pixel PX3, and a fourth sub-pixel PX4. Exemplarily, the first sub-pixel PX1 may be set as a red sub-pixel, the second sub-pixel PX2 and the third sub-pixel PX3 may be set as green sub-pixels, and the fourth sub-pixel PX4 may be set as a blue sub-pixel. However, the embodiments of the present disclosures are not limited thereto. For example, the first sub-pixel PX1, the second sub-pixel PX2, the third sub-pixel PX3 and the fourth sub-pixel PX4 may also be set as a red sub-pixel, a green sub-pixel, a blue sub-pixel and a white sub-pixel, respectively.

The display substrate further includes a plurality of gate lines GL and a plurality of data lines DL provided on the base substrate 200 and located at least in the display area AA. The plurality of gate lines GL extend in a first direction X, and the plurality of data lines DL extend in a second direction Y. The second direction intersects with the first direction X. For example, the first direction X may include a horizontal direction in FIG. 1, and the second direction Y may include a vertical direction in FIG. 1, that is, the first direction X and the second direction Y are perpendicular to each other.

For example, a sub-pixel PX is connected to one data line DL and one gate line GL. For example, the plurality of sub-pixels PX on the display substrate may be divided into a plurality of sub-pixel groups, a sub-pixel group includes a plurality of sub-pixels PX arranged in the first direction X, and the plurality of sub-pixel groups are arranged in the second direction Y.

A gate line GL is connected to one sub-pixel group to supply a turn-on voltage to that sub-pixel group. The plurality of sub-pixels PX in the sub-pixel group are connected to different data lines DL, respectively, so that data voltages may be respectively supplied to the plurality of sub-pixels PX according to display needs when the turn-on voltage is supplied to that sub-pixel group.

The peripheral area NA may be arranged on at least one side of the display area AA. For example, the peripheral area NA may surround a periphery of the display area AA. In the embodiments of the present disclosure, the peripheral area NA may include a transverse portion extending in the first direction X and a longitudinal portion extending in the second direction Y.

The display substrate may further include a gate driver circuit 21 and a driver chip 22, which are provided on the base substrate 200 and located in the peripheral area NA. For example, the gate driver circuit 21 may be provided on at least one side of the display area AA. In the embodiment shown in FIG. 1, gate driver circuits 21 are provided on a left side and a right side of the display area AA, respectively. It will be noted that the left side and the right side may refer to a left side and a right side of the display substrate (screen) viewed by human eyes during display. For example, the driver chip 22 may be provided on at least one side of the display area AA. In the embodiment shown in FIG. 1, the driver chip 22 is provided on a lower side of the display area AA. It will be noted that the lower side may be a lower side of the display substrate (screen) viewed by human eyes during display.

The driver chip 22 includes a data driver circuit, which is used to sequentially latch input data periodically according to clock signals and convert the latched data into analog signals, and then input the analog signals to the data lines DL on the display substrate. The gate driver circuit 21 is generally implemented by a shift register, which converts the clock signals into on/off voltages and outputs the on/off voltages to the gate lines GL on the display substrate.

It will be noted that FIG. 1 shows that the gate driver circuits 21 are on the left side and the right side of the display area AA, and the driver chip 22 is on the lower side of the display area AA. However, the embodiments of the present disclosure are not limited thereto. The gate driver circuits 21 and the driver chip 22 may be provided at any suitable positions in the peripheral area NA.

For example, a GOA technology, namely Gate Driver on Array, may be adopted for the gate driver circuit 21. According to the GOA technology, the gate driver circuit 21 is provided directly on an array substrate to replace an external chip. Each GOA unit serves as a stage of shift register, and each stage of shift register is connected to a gate line GL. Scanning signals are sequentially output through the respective stages of shift registers, so as to achieve progressive scanning of the pixel units. In some embodiments, each stage of shift register may also be connected to a plurality of gate lines GL. In this way, it may adapt to a development trend of high resolution and narrow bezel of display substrates. The driver chip 22 may be folded to a back side of the display substrate using a structure such as a chip on film, so as to contribute to the narrowing of the lower bezel.

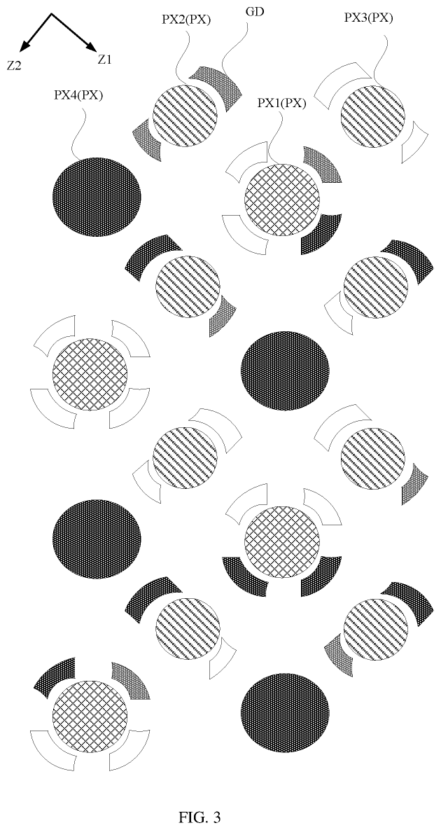

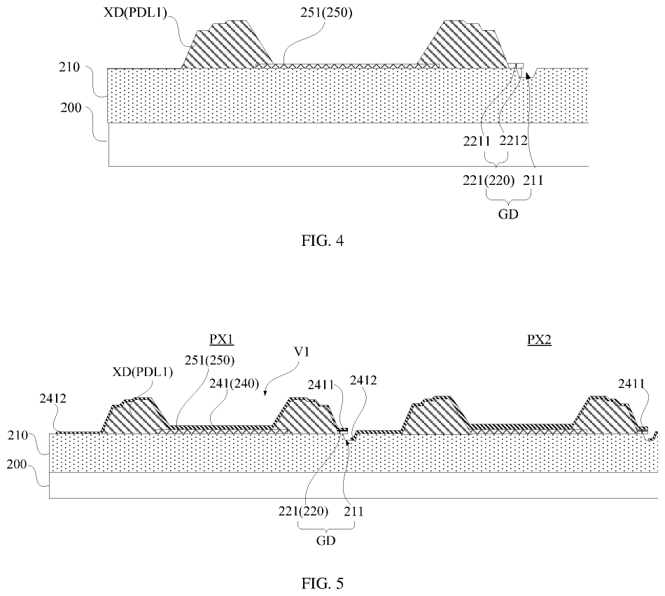

FIG. 3 schematically shows a top view of sub-pixels and partition structures according to an embodiment of the present disclosure. FIG. 4 schematically shows a cross-sectional view of sub-pixels and partition structures according to an embodiment of the present disclosure.

Referring to FIG. 3 and FIG. 4, the display substrate of the embodiments of the present disclosure includes a first planarization layer 210 provided on the base substrate 200. The display substrate further includes a pixel circuit layer provided on the base substrate 200. The first planarization layer 210 is provided on a side of the pixel circuit layer away from the base substrate 200, and may be a continuous integral layer. The first planarization layer 210 is used to reduce a step difference, so as to provide a flat substrate for subsequent components (such as light-emitting devices).

A partition structure GD is provided between two sub-pixels adjacent to each other PX. The two sub-pixels adjacent to each other PX may specifically refer to two sub-pixels PX adjacent to each other in a predetermined direction, without other sub-pixels PX between the two sub-pixels. Optionally, the predetermined direction may be determined according to actual needs, which is not limited here, as long as the partition structure GD is provided between two sub-pixels PX adjacent to each other in some direction in the embodiments of the present disclosure. For example, the predetermined direction may include either the first direction X or the second direction Y, or the predetermined direction may include both the first direction X and the second direction Y. For example, the predetermined direction may include a direction that intersects with both the first direction X and the second direction Y. The partition structure GD may separate the charge generation portions 241 of two sub-pixels PX adjacent to each other, so as to prevent the current from being conducted between the two sub-pixels PX through the charge generation portions 241.

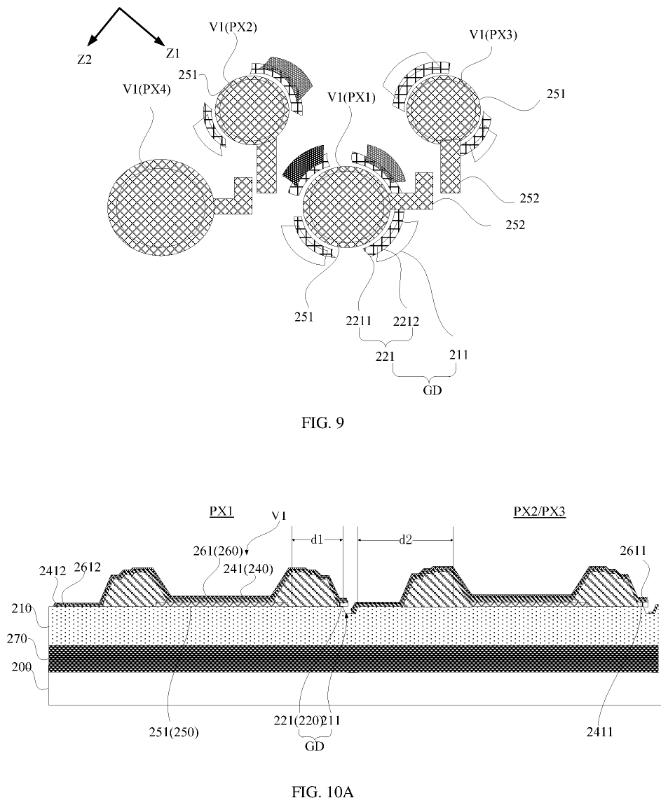

Optionally, the predetermined direction may be adaptively determined according to the current pixel structure. For example, referring to FIG. 3, an RGGB pixel structure is adopted in the display substrate in the embodiments of the present disclosure. The first sub-pixel PX1 may be set as a red sub-pixel PX, the second sub-pixel PX2 and the third sub-pixel PX3 may be set as green sub-pixels PX, and the fourth sub-pixel PX4 may be set as a blue sub-pixel PX. In such pixel structure, the first sub-pixels PX1 and the second sub-pixels PX2 are alternately arranged in a third direction Z1, the first sub-pixels PX1 and the third sub-pixels PX3 are alternately arranged in a fourth direction Z2, the second sub-pixels PX2 and the fourth sub-pixels PX4 are alternately arranged in the fourth direction Z2, and the third sub-pixels PX3 and the fourth sub-pixels PX4 are alternately arranged in the third direction Z1. The first direction X, the second direction Y, the third direction Z1 and the fourth direction Z2 intersect with one another, and the predetermined direction may include the third direction Z1 and the fourth direction Z2. A spacing between two sub-pixels PX adjacent to each other in the third direction Z1 (the fourth direction Z2) is less than a spacing between two sub-pixels PX adjacent to each other in the first direction X (the second direction Y), and there is a higher risk of current crosstalk in the two sub-pixels PX adjacent to each other in the third direction Z1 (fourth direction Z2). Therefore, referring to FIG. 3, a partition structure GD is provided between the two sub-pixels PX adjacent to each other in the third direction Z1 (the fourth direction Z2), so that the current crosstalk problem between sub-pixels PX adjacent to each other may be effectively reduced. Moreover, providing a partition structure GD between two sub-pixels PX adjacent to each other in the third direction Z1 (the fourth direction Z2) may contribute to a less impact on the existing structures. For example, referring to FIG. 9, in a same sub-pixel PX, a first electrode 251 needs to be electrically connected to a pixel circuit through a first connecting portion 252, and the first connecting portion 252 extends in the first direction X or the second direction Y. Providing the partition structure GD between two sub-pixels PX adjacent to each other in the third direction Z1 (the fourth direction Z2) may prevent the partition structure GD from separating the first connecting portion 252.

Referring to FIG. 3 and FIG. 4, the display substrate further includes a first passivation layer 220 provided on a side of the first planarization layer 210 away from the base substrate 200. The partition structure GD includes a partition portion 221 and a first groove 211. The partition portion 221 is in the first passivation layer 220, and the first groove 211 is in the first planarization layer 210. An orthographic projection of the partition portion 221 on the base substrate 200 overlaps partially with an orthographic projection of the first groove 211 on the base substrate 200.

For clarity, unless otherwise specified, first sub-pixel PX1 and second sub-pixel PX2 adjacent to each other are taken as examples below for description.

FIG. 5 schematically shows a first cross-sectional view of two sub-pixels adjacent to each other according to an embodiment of the present disclosure.

Referring to FIG. 5, a left sub-pixel PX is the first sub-pixel PX1, and a right sub-pixel PX is the second sub-pixel PX2. The partition portion 221 is provided between the first sub-pixel PX1 and the second sub-pixel PX2. The partition portion 221 covers a left half of the first groove 211 and exposes a right half of the first groove 211. A left side wall of the first groove 211 is grooved leftwards relative to the partition portion 211, so that an undercut structure may be formed by the partition portion 221 and the left half of the first groove 211.

In the embodiments of the present disclosure, the first groove 211 may be formed after the partition portion 221. For example, a first planarization material layer is prepared on the base substrate 200 first, and a material of the first planarization material layer includes a photoresist material. The first planarization material layer may undergo denaturation after being exposed to light, and a denatured portion may be removed after development. Then, the partition portion 221 is formed on a region where the first groove 211 is to be formed in the first planarization material layer. The partition portion 221 may include a transparent material, that is, the partition portion 221 allows light to pass through. Subsequently, the region where the first groove 211 is to be formed in the first planarization material layer is exposed using a mask pattern to denature that region. Finally, the region where the first groove 211 is to be formed is etched by using a wet etching or selective dry etching process, while the partition portion 221 is retained, thereby forming the first groove 211 partially covered by the partition portion 221.

FIG. 6 schematically shows a cross-sectional view of a light-emitting device according to an embodiment of the present disclosure.

Referring to FIG. 5 and FIG. 6, the display substrate further includes an organic light-emitting layer 230 and an organic common layer 240, which are provided on a side of the first passivation layer 220 away from the base substrate 200.

At least one sub-pixel PX includes an organic light-emitting device OL. The organic light-emitting device OL includes a light-emitting portion 231 and a charge generation portion 241, the light-emitting portion 231 is in the organic light-emitting layer 230, and the charge generation portion 241 is in the organic common layer 240.

The charge generation portion 241 may include at least one of a hole transport layer, a hole injection layer, an electron transport layer, or an electron injection layer. The hole injection layer is on a side of the light-emitting portion 231 proximate to the base substrate 200, the hole transport layer is between the light-emitting portion 231 and the hole injection layer, the electron injection layer is on a side of the light-emitting portion away from the base substrate 200, and the electron transport layer is between the light-emitting portion 231 and the electron injection layer.

For two sub-pixels PX adjacent to each other and the partition structure GD between the two sub-pixels PX adjacent to each other, the charge generation portion 241 of one sub-pixel PX includes a first extension sub-portion 2411 extending between the two sub-pixels PX, and the charge generation portion 241 of the other sub-pixel PX includes a second extension sub-portion 2412 extending between the two sub-pixels PX.

For example, the charge generation portion 241 may be formed by using an evaporation process. The charge generation portion 241 is located in an effective light-emitting region of the sub-pixel PX and further extends towards an adjacent sub-pixel PX. The effective light-emitting region may refer to a region defined by a pixel opening V1 of the sub-pixel PX.

Referring to FIG. 5, in the first sub-pixel PX1, a portion of the charge generation portion 241 extends towards the second sub-pixel PX2 on the right, and that portion is the first extension sub-portion 2411 of the first sub-pixel PX1. Accordingly, in the second sub-pixel PX2, a portion of the charge generation portion 241 extends towards the first sub-pixel PX1 on the left, and that portion is the second extension sub-portion 2412 of the second sub-pixel PX2.

It will be noted that each sub-pixel PX may include a first extension sub-portion 2411 and a second extension sub-portion 2412. For example, referring to FIG. 5, in the first sub-pixel PX1, the portion of the charge generation portion 241 extending rightwards is the first extension sub-portion 2411, and the portion of the charge generation portion 241 extending leftwards is the second extension sub-portion 2412. Accordingly, in the second sub-pixel PX2, the portion of the charge generation portion 24 extending leftwards is the second extension sub-portion 2412, and the portion of the charge generation portion 241 extending rightwards is the first extension sub-portion 2411.

One of the first extension sub-portion 2411 and the second extension sub-portion 2412 is on a side of the partition portion 221 away from the base substrate 200, and the other is on the bottom wall of the first groove 211. The first extension sub-portion 2411 and the second extension sub-portion 2412 are insulated and spaced apart from each other. For example, referring to FIG. 5, the first extension sub-portion 2411 in the first sub-pixel PX1 is located on the partition portion 221, and the second extension sub-portion 2412 in the second sub-pixel PX2 is on the bottom wall of the first groove 211. In this way, the first extension sub-portion 2411 and the second extension sub-portion 2412 have a height difference therebetween in the vertical direction, so that the two are insulated and spaced apart from each other.

In other words, the partition structure GD may separate the charge generation portions 241 of two sub-pixels PX adjacent to each other without changing the preparation process of the charge generation portion 241, so as to prevent the current from being conducted between the two sub-pixels PX adjacent to each other through the charge generation portions 241 of the two sub-pixels PX adjacent to each other, and thus the problem of crosstalk and color shift caused by this may be alleviated. Moreover, in the embodiments of the present disclosure, the partition portion partially covers the first groove to form the undercut structure. The first planarization layer 210 has a large thickness, and forming a groove in the first planarization layer 210 to form the undercut structure may not affect the existing structures. In addition, due to the large thickness of the first planarization layer 210, the first extension sub-portion 2411 and the second extension sub-portion 2412 may have a sufficient height difference, so as to ensure a misalignment of the two, thereby preventing the connection between the two caused by process fluctuations.

A further description of the embodiments of the present disclosure will be provided below with reference to FIG. 1 to FIG. 22.

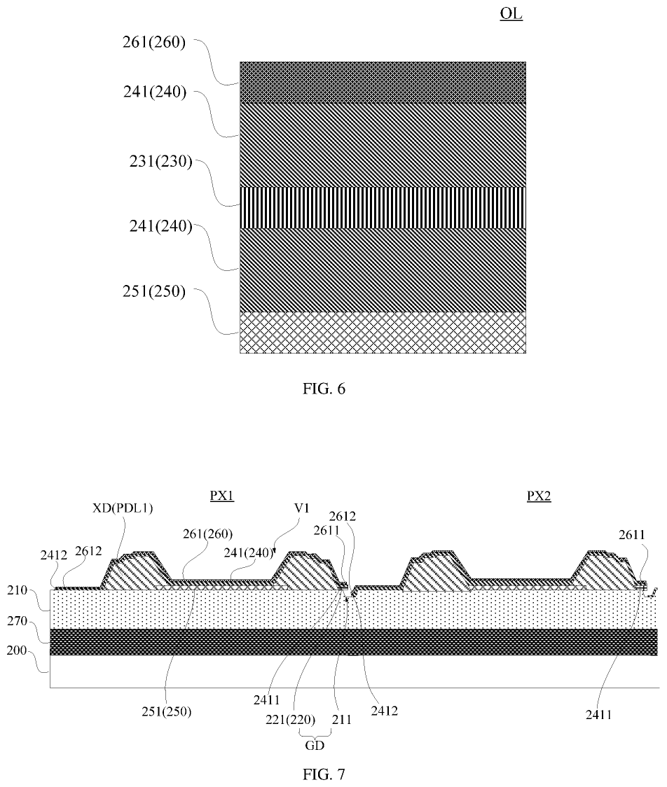

FIG. 7 schematically shows a second cross-sectional view of two sub-pixels adjacent to each other according to an embodiment of the present disclosure.

Referring to FIG. 6 and FIG. 7, in some specific embodiments, the display substrate further includes a first electrode layer 250, a second electrode layer 260, and a pixel circuit layer 270. The first electrode layer 250 is on a side of the organic light-emitting layer 230 proximate to the base substrate 200, the second electrode layer 260 is on a side of the organic light-emitting layer 230 away from the base substrate 200, and the pixel circuit layer 270 is on a side of the first planarization layer 210 proximate to the base substrate 200.

At least one sub-pixel PX further includes a pixel circuit, and the organic light-emitting device OL further includes a first electrode 251 and a second electrode 261. The first electrode 251 is in the first electrode layer 250, and the second electrode 261 is in the second electrode layer 260. One of the first electrode 251 and the second electrode 261 is an anode, and the other is a cathode. For example, the first electrode 251 is the anode, and the second electrode 261 is the cathode. The first electrode 251 is electrically connected to the pixel circuit, and the second electrode 261 is electrically connected to a first voltage terminal that may provide a constant low-level voltage.

One of the first electrode 251 and the second electrode 261 is a reflective electrode, and the other is a semi-transparent and semi-reflective electrode. Whether the first electrode 251 is provided as a transparent electrode or a semi-transparent electrode, or the second electrode 261 is provided as a transparent electrode or a semi-transparent electrode, light is emitted from the transparent electrode or the semi-transparent electrode.

For two sub-pixels PX adjacent to each other and the partition structure GD between the two sub-pixels PX, the second electrode 261 of one sub-pixel PX includes a third extension sub-portion 2611 extending between the two sub-pixels PX, and the second electrode 261 of the other sub-pixel PX includes a fourth extension sub-portion 2612 extending between the two sub-pixels PX. The third extension sub-portion 2611 is on a side of the first extension sub-portion 2411 away from the base substrate 200, and the fourth extension sub-portion 2612 is on a side of the second extension sub-portion 2412 away from the base substrate 200. The third extension sub-portion 2611 and the fourth extension sub-portion 2612 are insulated and spaced apart from each other.

For example, referring to FIG. 7, the second electrode 261 of the first sub-pixel PX1 includes the third extension sub-portion 2611 extending rightwards between the first sub-pixel PX1 and the second sub-pixel PX2, and the second electrode 261 of the second sub-pixel PX2 includes the fourth extension sub-portion 2612 extending leftwards between the second sub-pixel PX2 and the first sub-pixel PX1.

The second electrode 261 may be formed by using an evaporation process. The second electrode 261 is provided in the effective light-emitting region of the sub-pixel PX, and further extends towards an adjacent sub-pixel PX. Referring to FIG. 7, in the first sub-pixel PX1, a portion of the second electrode 261 extends towards the second sub-pixel PX2 on the right, and that portion is the third extension sub-portion 2611 of the first sub-pixel PX1. Accordingly, in the second sub-pixel PX2, a portion of the second electrode 261 extends towards the first sub-pixel PX1 on the left, and that portion is the fourth extension sub-portion 2612 of the second sub-pixel PX2.

It will be noted that in the embodiments of the present disclosure, each sub-pixel PX may include the third extension sub-portion 2611 and the fourth extension sub-portion 2612. For example, referring to FIG. 7, in the first sub-pixel PX1, the portion of the second electrode 261 extending rightwards is the third extension sub-portion 2611, and the portion of the second electrode 261 extending leftwards is the fourth extension sub-portion 2612. Accordingly, in the second sub-pixel PX2, the portion of the second electrode 261 extending leftwards is the fourth extension sub-portion 2612, and the portion of the second electrode 261 extending rightwards is the third extension sub-portion 2611.

Referring to FIG. 7, the third extension sub-portion 2611 in the first sub-pixel PX1 is farther away from the base substrate 200 than the first extension sub-portion 2411 in the first sub-pixel PX1, and the fourth extension sub-portion 2612 in the second sub-pixel PX2 is farther away from the base substrate 200 than the second extension sub-portion 2412 in the second sub-pixel PX2, so that the third extension sub-portion 2611 and the fourth extension sub-portion 2612 also have a height difference therebetween in the vertical direction, and thus the two are insulated and spaced apart from each other.

In this way, the second electrodes 261 of the two sub-pixels PX adjacent to each other may also be separated by the partition structure GD without changing the preparation process of the second electrodes 261, so that the current path between two sub-pixels PX adjacent to each other may be further blocked, which in turn contributes to a further reduction the problems of crosstalk and color shift.

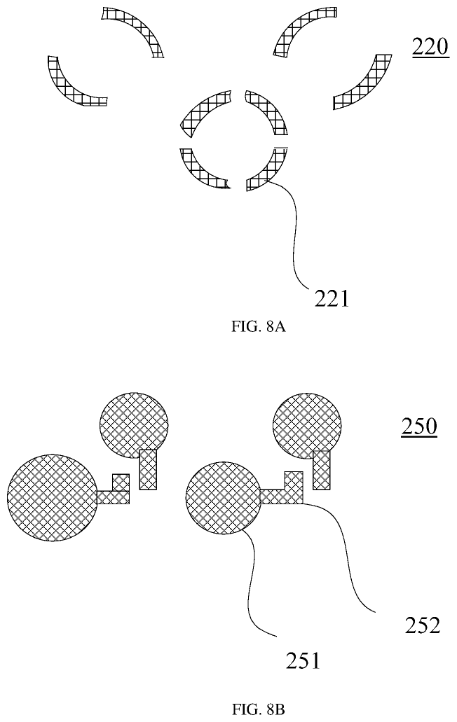

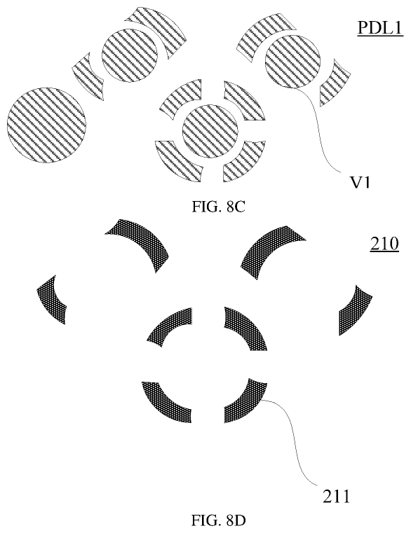

FIG. 8A to FIG. 9 schematically show a first top view of sub-pixels in a repetitive unit according to an embodiment of the present disclosure. FIG. 8A schematically shows a first top view of a first passivation layer according to an embodiment of the present disclosure, FIG. 8B schematically shows a top view of a first electrode layer according to an embodiment of the present disclosure, FIG. 8C schematically shows a top view of a first pixel defining layer according to an embodiment of the present disclosure, FIG. 8D schematically shows a top view of a first groove according to an embodiment of the present disclosure, and FIG. 9 schematically shows a first top view of a first passivation layer, a first electrode layer, a first pixel defining layer and a first groove according to an embodiment of the present disclosure.

Referring to FIG. 7 to FIG. 9, in some specific embodiments, at least one sub-pixel PX further includes a first connecting portion 252. In a same sub-pixel PX, the first electrode 251 is electrically connected to the pixel circuit through the first connecting portion 252. Optionally, the first connecting portion 252 may extend in the first direction X or the second direction Y. For example, at least part of the first connecting portion 252 of the first sub-pixel PX1 and at least part of the first connecting portion 252 of the fourth sub-pixel PX4 may extend in the first direction X, and the first connecting portion 252 of the second sub-pixel PX2 and the first connecting portion 252 of the third sub-pixel PX3 may extend in the second direction Y. The orthographic projection of the first groove 211 on the base substrate 200 does not overlap with an orthographic projection of the first connecting portion 252 on the base substrate 200, so that the first groove 211 may avoid a connection path between the first electrode 251 and the pixel circuit.

In some specific embodiments, the partition portion 221 includes a first partition sub-portion 2211 and a second partition sub-portion 2212. The first partition sub-portion 2211 covers a surface of the first planarization layer 210 on a side away from the base substrate 200. The orthographic projection of the first groove 211 on the base substrate 200 covers an orthographic projection of the second partition sub-portion 2212 on the base substrate, and an orthographic projection of the first partition sub-portion 2211 on the base substrate 200 at least partially surrounds the orthographic projection of the second partition sub-portion 2212 on the base substrate 200.

Optionally, the partition portion 2211 may be arranged in close proximity of at least one sub-pixel PX. For example, an orthographic projection of the partition portion 2211 on the base substrate 200 is contiguous with or even overlaps with the orthographic projection of the first electrode 251 of at least one sub-pixel PX on the base substrate 200.

The sub-pixel PX includes a pixel opening V1. An orthographic projection of the pixel opening V1 on the base substrate 200 is substantially a circle. An orthographic projection of the partition portion 221 on the base substrate 200 may include an arc-shaped pattern, which at least partially surrounds a periphery of the orthographic projection of the pixel opening V1 on the base substrate 200.

For example, the orthographic projection of the first electrode 251 on the base substrate 200 and the orthographic projection of the pixel opening V1 on the base substrate 200 are concentric circles, and a diameter of the orthographic projection of the first electrode 251 on the base substrate 200 is greater than a diameter of the orthographic projection of the pixel opening V1 on the base substrate 200. The arc-shaped pattern fits with an edge contour of the orthographic projection of the first electrode 251 on the base substrate 200.

It will be noted that the embodiments of the present disclosures are not limited to the aforementioned shapes. For example, the orthographic projection of the pixel opening V1 on the base substrate 200 may also have a shape including a square, a rectangle, a, or an irregular shape. Accordingly, the shape of the partition portion 221 may be appropriately changed so that the orthographic projection of the partition portion 221 on the base substrate 200 may at least partially surround the periphery of the aforementioned shapes.

Optionally, when the orthographic projection of the partition portion 221 on the base substrate 200 is in a shape of an arc, two ends of the first partition sub-portion 2211 in a circumferential direction of the first partition sub-portion 2211 extend to two sides of the second partition sub-portion 2212 in a circumferential direction of the second partition sub-portion 2212, so that the first partition sub-portion 2211 at least partially surrounds the second partition sub-portion 2212. This may contribute to an increase of an area of the first partition sub-portion 2211, for example, the area of the first partition sub-portion 2211 is greater than or equal to an area of the second partition sub-portion 2212. That is to say, an area of a portion of the partition portion 221 attached to the first planarization layer 210 is greater than an area of a suspended portion of the partition portion 221, so that the partition portion 221 may be more firmly attached to the first planarization layer 210, thereby preventing the partition portion 221 from warping or even peeling from the first planarization layer 210 in a subsequent etching process.

In some specific embodiments, the first groove 211 includes a first sub-groove and a second sub-groove, and an orthographic projection of the first sub-groove on the base substrate 200 overlaps with the orthographic projection of the second partition sub-portion 2212 on the base substrate 200. For two sub-pixels PX adjacent to each other and the partition structure GD between the two sub-pixels PX, in a direction from one sub-pixel PX to the other sub-pixel PX, the second partition sub-portion 2212 has a first size, and the second sub-groove has a second size, where the first size is less than or equal to the second size.

In some specific embodiments, in a direction from the first sub-pixel PX1 to the second sub-pixel PX2, the second partition sub-portion 2212 has the first size, and the second sub-groove has the second size, where the first size is less than or equal to the second size, so that an area of the first groove 211 covered by the partition portion 221 is less than or equal to an area of the first groove 211 exposed, which may facilitate the formation of an empty groove below the second partition sub-portion 2212 in the etching process, and may avoid a too large recess of the empty groove in the horizontal direction.

In the embodiments of the present disclosure, the direction from one sub-pixel PX to the other sub-pixel PX may refer to a direction of a line with a center of the pixel opening V1 of one sub-pixel PX as a starting point and a center of the pixel opening V1 of the other sub-pixel PX as an endpoint.

In some specific embodiments, for two sub-pixels PX adjacent to each other and the partition structure GD between the two sub-pixels PX, a size of the second sub-groove in the direction from one sub-pixel PX to the other sub-pixel PX is greater than or equal to a depth of the second sub-groove, and a size of the first sub-groove in the direction from one sub-pixel PX to the other sub-pixel PX is less than or equal to the depth of the second sub-groove. The first sub-groove and the second sub-groove have the same depth.

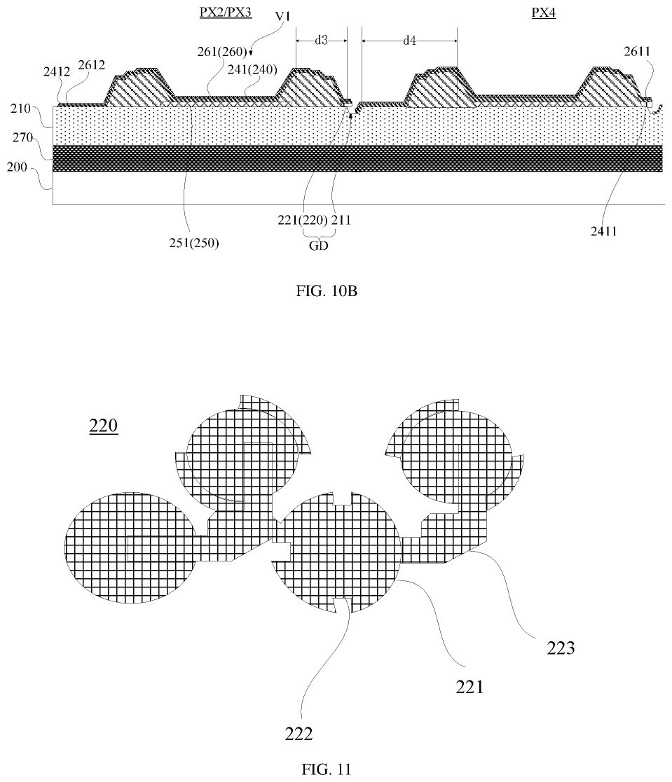

FIG. 10A and FIG. 10B schematically show a spacing between a first groove and a sub-pixel according to an embodiment of the present disclosure. FIG. 10A schematically shows a spacing between a first sub-pixel and a first groove which is between the first sub-pixel and a second sub-pixel (a third sub-pixel) and a spacing between the second sub-pixel (the third sub-pixel) and the first groove which is between the first sub-pixel and the second sub-pixel (third sub-pixel). FIG. 10B schematically shows a spacing between a fourth sub-pixel and a first groove which is between the fourth sub-pixel and a second sub-pixel (a third sub-pixel) and a spacing between the second sub-pixel (the third sub-pixel) and the first groove which is between the fourth sub-pixel and the second sub-pixel (the third sub-pixel).

Referring to FIG. 10A and FIG. 10B, in some specific embodiments, for two sub-pixels PX adjacent to each other and the partition structure GD between the two sub-pixels PX, in the direction from one sub-pixel PX to the other sub-pixel PX, a spacing d1 (d3) between the first groove 211 and one sub-pixel PX is less than a spacing d2 (d4) between the first groove 211 and the other sub-pixel PX. The first extension sub-portion 2411 of the sub-pixel PX that is spaced from the first groove 211 by a less spacing is on the side of the partition portion 221 away from the base substrate 200, and the second extension sub-portion 2412 of the sub-pixel PX that is spaced from the first groove 211 by a greater spacing is on the bottom wall of the first groove 211.

Herein, unless otherwise specified, “a spacing between the first groove 211 and one sub-pixel PX” and similar expressions refer to a distance between an edge of the first groove 211 closest to the pixel opening V1 of the sub-pixel PX and an edge of the pixel opening V1 closest to the first groove 211.

Exemplarily, with reference to FIG. 10A and FIG. 10B, in a direction from the first sub-pixel PX1 to the second sub-pixel PX2 (the third sub-pixel PX3), the spacing d1 between the first sub-pixel PX1 and the first groove 211 is less than the spacing d2 between the second sub-pixel PX2 (the third sub-pixel PX3) and the first groove 211, that is, the first groove 211 is closer to the first sub-pixel PX1. The first extension sub-portion 2411 in the first sub-pixel PX1 is located above the partition portion 221, and the second extension sub-portion 2412 in the second sub-pixel PX2 is on the bottom wall of the first groove 211.

In a direction from the second sub-pixel PX2 (the third sub-pixel PX3) to the fourth sub-pixel PX4, a spacing d3 between the second sub-pixel PX2 (the third sub-pixel PX3) and the first groove 211 is less than a spacing d4 between the fourth sub-pixel PX4 and the first groove 211, that is, the first groove 211 is closer to the second sub-pixel PX2 (the third sub-pixel PX3). The first extension sub-portion 2411 in the second sub-pixel PX2 (the third sub-pixel PX3) is located above the partition portion 221, and the second extension sub-portion 2412 in the fourth sub-pixel PX4 is on the bottom wall of the first groove 211. In this way, it is possible to provide a plurality of first groove 211 in a staggered arrangement, so as to make more space for the first groove 211 with little or even not affecting the existing structures.

It will be noted that in the above descriptions, the first sub-pixel PX1, the second sub-pixel PX2, and the partition structure GD between the two are taken as examples. However, this does not constitute a limitation to the embodiments of the present disclosure. The partition structure GD may be provided between the first sub-pixel PX1 and the second sub-pixel PX2, between the second sub-pixel PX2 and the fourth sub-pixel PX4, and between the third sub-pixel PX3 and the fourth sub-pixel PX4. A longitudinal cross-sectional structure of each partition structure GD and two sub-pixels PX adjacent to that partition structure GD may be provided with reference to the above examples and will not be described one by one in the embodiments of the present disclosure.

Referring to FIG. 7 to FIG. 9, in some specific embodiments, for two sub-pixels PX adjacent to each other and the partition structure GD between the two sub-pixels PX, the orthographic projection of the first electrode 251 of at least one sub-pixel PX on the base substrate 200 does not overlap with the orthographic projection of the partition portion 221 on the base substrate 200.

In the embodiments of the present disclosure, when forming the first passivation layer 220, only a necessary portion for forming the partition structure GD is retained, and other portions are removed to obtain the partition portion 221 on the periphery of the first electrode 251, so as to minimize a space occupied by the partition portion 221.

For example, referring to FIG. 9, for the first sub-pixel PX1 and four partition portions 221 (two of which may be connected to form an integral structure) in immediate proximity of the first sub-pixel PX1, each partition portion 221 partially surrounds the periphery of the first electrode 251 of the first sub-pixel PX1. Optionally, the first electrode 251 of the first sub-pixel PX1 is substantially in a shape of a circle, and the partition portion 221 surrounding the periphery of the first electrode 251 of the first sub-pixel PX1 is substantially in a shape of an arc accordingly. The second sub-pixel PX2 (the third sub-pixel PX3) is in immediate proximity of two partition portions 221 located on opposite sides of the second sub-pixel PX2 (the third sub-pixel PX3), and each partition portion 221 partially surrounds the periphery of the first electrode 251 of the second sub-pixel PX2 (third sub-pixel PX3). Optionally, the first electrode 251 of the second sub-pixel PX2 (the third sub-pixel PX3) is substantially in a shape of a circle, and the partition portion 221 surrounding the periphery of the first electrode 251 of the second sub-pixel PX2 (the third sub-pixel PX3) is in a shape of substantially an arc accordingly.

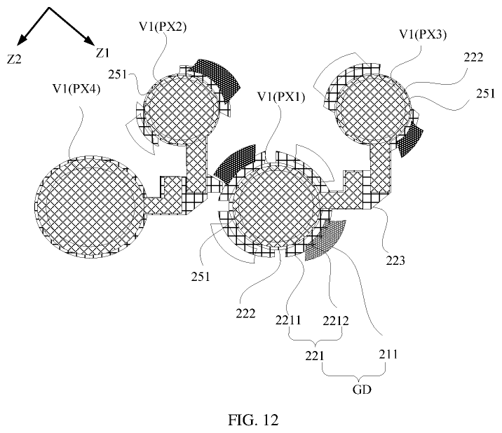

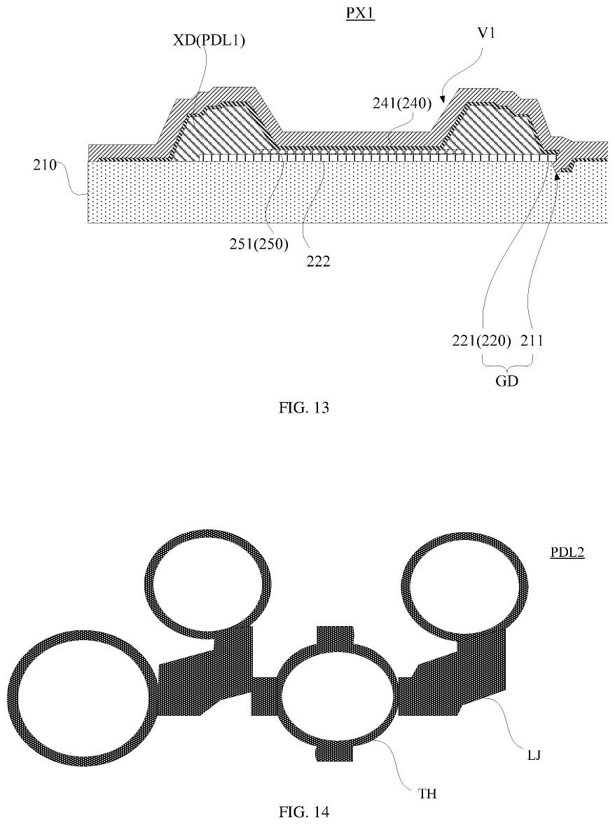

FIG. 11 and FIG. 12 schematically show a second top view of sub-pixels in a repetitive unit according to an embodiment of the present disclosure. FIG. 11 schematically shows a second top view of a first passivation layer according to an embodiment of the present disclosure. FIG. 12 schematically shows a second top view of a first passivation layer, a first electrode layer, a first pixel defining layer and a first groove according to an embodiment of the present disclosure. FIG. 13 schematically shows a third cross-sectional view of two sub-pixels adjacent to each other according to an embodiment of the present disclosure.

Referring to FIG. 11 to FIG. 13, in some specific embodiments, at least one sub-pixel PX further includes a first passivation portion 222 in the first passivation layer 220. In a same sub-pixel PX, an orthographic projection of the first passivation portion 222 on the base substrate 200 covers the orthographic projection of the first electrode 251 on the base substrate 200. For two sub-pixels PX adjacent to each other and the partition structure GD between the two sub-pixels PX, the first passivation portion 222 of one sub-pixel PX and the partition portion 221 are formed as an integral structure.

In the embodiments of the present disclosure, each partition portion 221 is in immediate proximity of at least one sub-pixel PX. For example, the orthographic projection of the partition portion 221 on the base substrate 200 is contiguous with or even overlaps with the orthographic projection of the first electrode 251 of at least one sub-pixel PX on the base substrate 200. The first passivation portion 222 and the partition portion 221 are provided in a same layer and made of a same material, and the two may be formed through single process. When forming the partition portion 221, as the partition portion 221 is close to the adjacent sub-pixel PX, there may be a residue below the first electrode 251, which affects a flatness of the first electrode 251. Therefore, in the embodiments of the present disclosure, when forming the first passivation layer 220, in addition to retaining the partition portion 221, a portion below the first electrode 251 is also retained, so that the first passivation portion 222 is formed synchronously. The flatness of the first electrode 251 may be ensured by providing the first passivation portion 222 below the first electrode 251.

Optionally, with reference to FIG. 8B and FIG. 12, the orthographic projection of the first passivation portion 222 on the base substrate 200 may cover not only the orthographic projection of the first electrode 251 on the base substrate 200, but also the orthographic projection of the first connecting portion 252 on the base substrate 200, thereby ensuring the overall flatness of the first electrode 251 and the first connecting portion 252.

Optionally, the first passivation portions 222 of at least two sub-pixels PX are formed as an integral structure through the second connecting portion 223. For example, with reference to FIG. 2 and FIG. 11, in a repetitive unit P, the first passivation portions 222 of the plurality of sub-pixels PX are connected to each other through the second connecting portion 223, and thus are form as an integral structure.

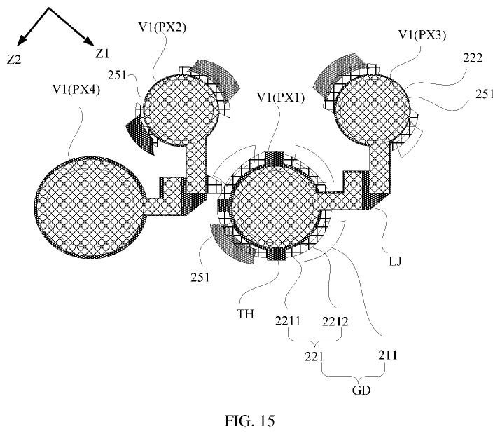

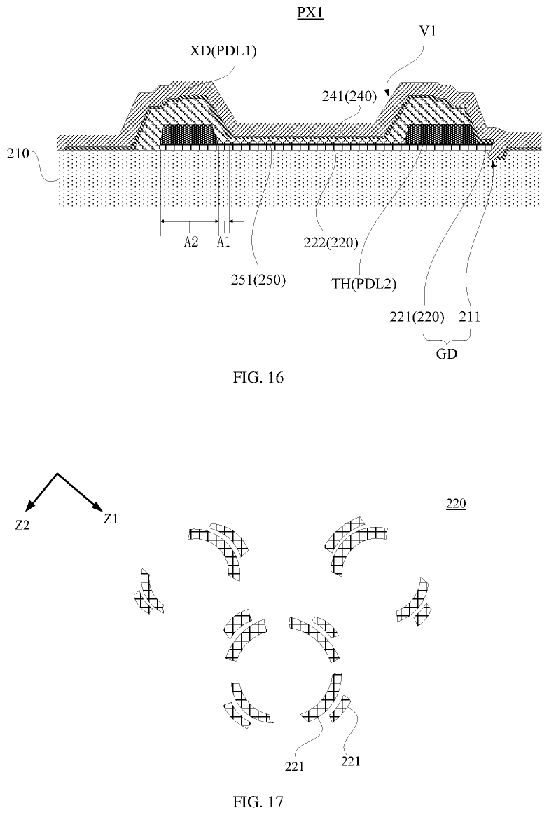

FIG. 14 and FIG. 15 schematically show a third top view of sub-pixels in a repetitive unit according to an embodiment of the present disclosure. FIG. 14 schematically shows a top view of a second pixel defining layer according to an embodiment of the present disclosure. FIG. 15 schematically shows a top view of a first passivation layer, a first electrode layer, a first pixel defining layer, a second pixel defining layer and a first groove according to an embodiment of the present disclosure. FIG. 16 schematically shows a fourth cross-sectional view of two sub-pixels adjacent to each other according to an embodiment of the present disclosure.

Referring to FIG. 14 to FIG. 16, in some specific embodiments, the display substrate further includes a first pixel defining layer PDL1 and a second pixel defining layer PDL2. The first pixel defining layer PDL1 is on a side of the first electrode 251 away from the base substrate 200, and the second pixel defining layer PDL2 is between the first pixel defining layer PDL1 and the first passivation layer 220. A material of the first pixel defining layer PDL1 includes a black pixel defining material, and a material of the second pixel defining layer PDL2 includes a transparent pixel defining material. At least one sub-pixel PX further includes a pixel defining portion XD and an auxiliary attaching portion TH. The pixel defining portion XD is in the first pixel defining layer PDL1, and the auxiliary attaching portion TH is in the second pixel defining layer PDL2. In a same sub-pixel PX, the pixel defining portion XD is configured to define an effective light-emitting region of the organic light-emitting device OL, and the pixel defining portion XD is attached to the first passivation portion 222 through the auxiliary attaching portion TH. A maximum thickness of the auxiliary attaching portion TH is less than or equal to a maximum thickness of the pixel defining portion XD.

In the embodiments of the present disclosure, the pixel defining portion XD is provided with a pixel opening V1, and a region defined by the pixel opening V1 is the effective light-emitting region of the organic light-emitting device OL. Referring to FIG. 15, the pixel opening V1 on the pixel defining portion XD defines an approximately circular region, which is the effective light-emitting region of the organic light-emitting device. It will be noted that this does not constitute a limitation to the embodiments of the present disclosure, and the pixel opening V1 in the embodiments of the present disclosures may be of any shape.

The pixel opening V1 may expose the first electrode 251 of the light-emitting device, so that the hole injection layer may be contact with the exposed first electrode 251 to achieve an electrical connection. Accordingly, the second electrode 261 may cover the pixel opening V1, so that the electron injection layer may be contact with the second electrode 261 to achieve an electrical connection.

Compared to the black pixel defining material, the transparent pixel defining material has a better attachment with the first passivation portion 222. Therefore, by using the auxiliary attaching portion TH including the transparent pixel defining material formed between the pixel defining portion XD and the first passivation portion 222, the pixel defining portion XD may be more firmly attached to the first passivation portion 222, thereby preventing the pixel defining portion XD from warping and peeling from the first passivation portion 222 in the process of etching the first groove 211. Moreover, the thickness of the auxiliary attaching portion TH is less than the thickness of the pixel defining portion XD, and a small thickness of the auxiliary attaching portion TH may help to minimize an influence on the film thickness and the flatness.

Referring to FIG. 14 to FIG. 16, in some specific embodiments, in a same sub-pixel PX, an orthographic projection of the pixel defining portion XD on the base substrate 200 overlaps with the orthographic projection of the first passivation portion 222 on the base substrate 200, and an overlap between the two defines a first pattern. The first pattern includes a middle region A1 and an edge region A2 outside the middle region A1. The orthographic projection of the first electrode 251 on the base substrate 200 covers the middle region A1, and the orthographic projection of the auxiliary attaching portion TH on the base substrate 200 covers the edge region A2.

In a same sub-pixel PX, the first electrode 251 and the auxiliary attaching portion TH cooperate to cover the first pattern as much as possible. An middle region of the first pattern is covered by the first electrode 251, and an edge region of the first pattern is covered by the auxiliary attaching portion TH, so that a contact area between the pixel defining part XD and the first passivation part 222 may be minimized, or even the pixel defining part XD is not contact with the first passivation portion 222.

In some specific embodiments, in a same sub-pixel PX, the orthographic projection of the auxiliary attaching portion TH on the base substrate 200 surrounds the orthographic projection of the first electrode 251 on the base substrate 200.

In a same sub-pixel PX (for example, in the first sub-pixel PX1), the orthographic projection of the first electrode 251 on the base substrate 200 includes a circular pattern, and the orthographic projection of the auxiliary attaching portion TH on the base substrate 200 includes a ring pattern accordingly. Optionally, the orthographic projection of the auxiliary attaching portion TH on the base substrate 200 may overlap with the orthographic projection of the first electrode 251 on the base substrate 200 to some degree, so as to prevent a case that the two overlap in some regions but do not overlap in some other regions due to process fluctuations, which may contribute to the improvement of the uniformity.

Optionally, the orthographic projection of the auxiliary attaching portion TH on the base substrate 200 may further cover an orthographic projection of the second connecting portion 223 on the base substrate 200, so that the first pixel defining layer PDL1 may be better attached to the second connecting portion 223 at this position.

Optionally, the auxiliary attaching portions TH of at least two sub-pixels PX are formed as an integral structure. For example, the auxiliary attaching portions TH of sub-pixels PX in a same repetitive unit P are connected to each other through a third connecting portion LJ to form as an integral structure.

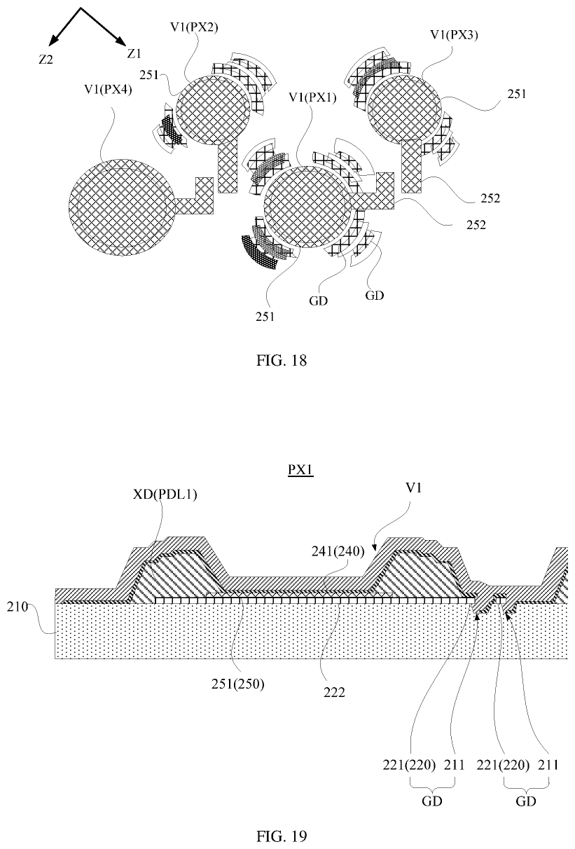

FIG. 17 and FIG. 18 schematically show a fourth top view of sub-pixels in a repetitive unit according to an embodiment of the present disclosure. FIG. 17 schematically shows a third top view of a first passivation layer according to an embodiment of the present disclosure. FIG. 18 schematically shows a third top view of a first passivation layer, a first electrode layer, a first pixel defining layer and a first groove according to an embodiment of the present disclosure. FIG. 19 schematically shows a fifth cross-sectional view of two sub-pixels adjacent to each other according to an embodiment of the present disclosure.

Referring to FIG. 17 to FIG. 19, in some specific embodiments, a plurality of partition structures GD are provided between two sub-pixels PX adjacent to each other, and at least two partition structures GD have different areas.

In the embodiments of the present disclosure, between the two sub-pixels PX adjacent to each other, each of the plurality of partition structures GD may include sequentially arranged arcs. In the first sub-pixel PX1 and a plurality of partition structures GD adjacent to the first sub-pixel PX1, the farther away from the first sub-pixel PX1, the smaller the area of the partition structure GD. In the second sub-pixel PX2 and a plurality of partition structures GD adjacent to the second sub-pixel PX2 in the fourth direction Z2, the farther away from the second sub-pixel PX2, the smaller the area of the partition structure GD. In the third sub-pixel PX3 and a plurality of partition structures GD adjacent to the third sub-pixel PX3 in the third direction Z1, the farther away from the third sub-pixel PX3, the smaller the area of the partition structure GD.

In this way, the partition effect may be further enhanced through the plurality of partition structures GD, while an area occupied by the partition structures GD may be reduced as small as possible.

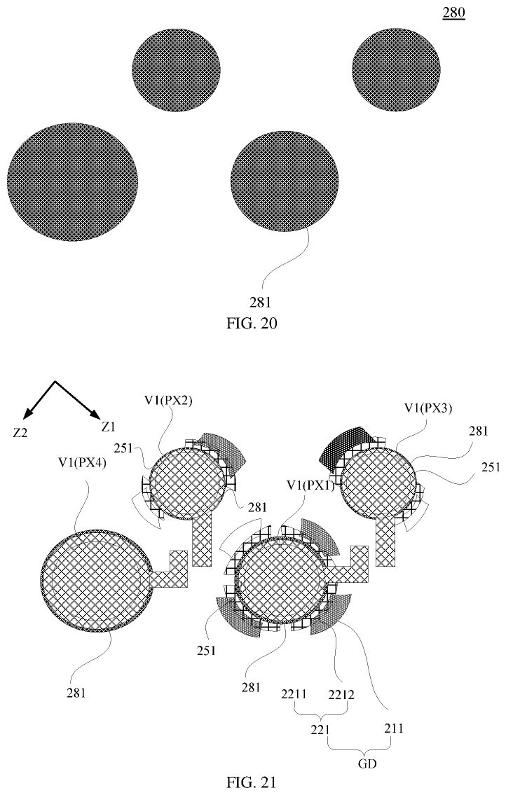

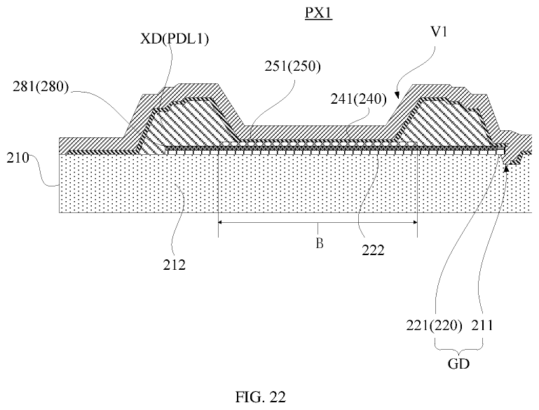

FIG. 20 and FIG. 21 schematically show a fifth top view of sub-pixels in a repetitive unit according to an embodiment of the present disclosure. FIG. 20 schematically shows a top view of a second planarization layer according to an embodiment of the present disclosure. FIG. 21 schematically shows a top view of a first passivation layer, a first electrode layer, a first pixel defining layer, a second planarization layer and a first groove according to an embodiment of the present disclosure. FIG. 22 schematically shows a sixth cross-sectional view of two sub-pixels adjacent to each other according to an embodiment of the present disclosure.

Referring to FIG. 20 to FIG. 22, in some specific embodiments, the display substrate further includes a second planarization layer 280 between the first passivation layer 220 and the first electrode 251. At least one sub-pixel PX further includes a first spacing portion 281 in the second planarization layer 280. In a same sub-pixel PX, the orthographic projection of the first electrode 251 on the base substrate 200 overlaps with the orthographic projection of the first passivation portion 222 on the base substrate 200, and an overlap between the two defines a second pattern B. An orthographic projection of the first spacing portion 281 on the base substrate 200 covers the second pattern B.

In the embodiments of the present disclosure, a shape of the first spacing portion 281 is substantially the same as a shape of the first electrode 251, and the first spacing portion 281 is slightly larger than the first electrode 251, and thus is filled between the first electrode 251 and the first passivation portion 222. A material of the first planarization layer 210 may be the same as a material of the second planarization layer 280. The first spacing portion 281 located in the second planarization layer 280 has a better flexibility than the first passivation portion 222. By filling the first spacing portion 281 between the first electrode 251 and the first passivation portion 222, it is possible to further improve the flatness of the first electrode 251.

In some specific embodiments, in a same sub-pixel PX, the orthographic projection of the pixel defining portion XD on the base substrate 200 overlaps with the orthographic projection of the first passivation portion 222 on the base substrate 200, and an overlap between the two defines a first pattern. The orthographic projection of the first spacing portion 281 on the base substrate 200 covers the first pattern.

In the embodiments of the present disclosure, in addition to the filling between the first electrode 251 and the first passivation portion 222, the first spacing portion 281 further extends outward and thus be filled between the pixel defining portion XD and the first passivation portion 222, so as to improve attachment between the pixel defining portion XD and the first passivation portion 222 and prevent the two from warping and peeling off.

In some specific embodiments, at least one sub-pixel PX further includes a first planarization portion 212, which is located in the first planarization layer 210. In a same sub-pixel PX, a thickness of the first spacing portion 281 is less than or equal to a thickness of the first passivation portion 222, and the thickness of the first passivation portion 222 is less than a thickness of the first planarization portion 212.

In the embodiments of the present disclosure, the thickness of the first spacing portion 281 is small, so that the first spacing portion 281 has a small impact on an overall film thickness of the display substrate. Optionally, the thickness of the first planarization portion 212 may be reduced, so that the overall film thickness of the display substrate is substantially the same or even unchanged before and after the addition of the first spacing portion 281.

Referring to FIG. 9 to FIG. 10B, in some specific embodiments, the plurality of sub-pixels PX include a first sub-pixel PX1, a second sub-pixel PX2, and a third sub-pixel PX3. The first sub-pixel PX1 and the second sub-pixel PX2 have different colors, and the second sub-pixel PX2 and the third sub-pixel PX3 have the same color. For the first sub-pixel PX1, the second sub-pixel PX2 adjacent to the first sub-pixel PX1, and the partition structure GD between the first sub-pixel PX1 and the second sub-pixel PX2, in the direction from the first sub-pixel PX1 to the second sub-pixel PX2, the spacing d1 between the first groove 211 and the first sub-pixel PX1 is less than the spacing d2 between the first groove 211 and the second sub-pixel PX2. For the first sub-pixel PX1, the third sub-pixel PX3 adjacent to the first sub-pixel PX1, and the partition structure GD between the first sub-pixel PX1 and the third sub-pixel PX3, in the direction from the first sub-pixel PX1 to the third sub-pixel PX3, the spacing d1 between the first groove 211 and the first sub-pixel PX1 is less than the spacing d2 between the first groove 211 and the third sub-pixel PX3.

For example, the first sub-pixel PX1 may be provided as a red sub-pixel, and the second sub-pixel PX2 and the third sub-pixel PX3 may be provided as green sub-pixels PX. The plurality of sub-pixels PX further include a fourth sub-pixel PX4, which may be provided as a blue sub-pixel PX. That is to say, the aforementioned RGGB pixel structure may be adopted in the embodiments of the present disclosure.

In some specific embodiments, the display substrate further includes a plurality of gate lines GL and a plurality of data lines DL. The plurality of gate lines GL extend in the first direction X, and the plurality of data lines DL extend in the second direction Y. The first sub-pixels PX1 and the second sub-pixels PX2 are alternately arranged in the third direction Z1, the first sub-pixels PX1 and the third sub-pixels PX3 are alternately arranged in the fourth direction Z2, the third sub-pixels PX3 and the fourth sub-pixels PX4 are alternately arranged in the third direction Z1, and the second sub-pixels PX2 and the fourth sub-pixels PX4 are alternately arranged in the fourth direction Z2. The first direction X, the second direction Y, the third direction Z1 and the fourth direction Z2 intersect with one another.

Optionally, the third direction Z1 and the fourth direction Z2 are perpendicular to each other, and an included angle between the third direction Z1 and the first direction X or between the fourth direction Z2 and the first direction X may be set to 45°.

In the embodiments of the present disclosure, the partition structure GD between two sub-pixels PX adjacent to each other is spaced from the two sub-pixels PX by different distances. For example, for the first sub-pixel PX1, the partition structures GD between the first sub-pixel PX1 and other sub-pixels PX are arranged closer to the first sub-pixel PX1. For example, the partition structure GD between the first sub-pixel PX1 and the second sub-pixel PX2 is arranged closer to the first sub-pixel PX1, and the partition structure GD between the first sub-pixel PX1 and the third sub-pixel PX3 is also arranged closer to the first sub-pixel PX1.

Referring to FIG. 9, in some specific embodiments, orthographic projections of the partition structures GD adjacent to the first sub-pixel PX1 on the base substrate define a third pattern, which at least partially surrounds the orthographic projection of the pixel opening V1 of the first sub-pixel PX1 on the base substrate 200. Thus, the partition structures GD around the first sub-pixel PX1 fit with the pixel opening V1 of the first sub-pixel PX1, so that a space utilization may be improved.

In some specific embodiments, for the third sub-pixel PX3, the fourth sub-pixel PX4 adjacent to the third sub-pixel PX3, and the partition structure GD between the third sub-pixel PX3 and the fourth sub-pixel PX4, in the direction from the third sub-pixel PX3 to the fourth sub-pixel PX4, the spacing d3 between the first groove 211 and the third sub-pixel PX3 is less than the spacing d4 between the first groove 211 and the fourth sub-pixel PX4. For the second sub-pixel PX2, the fourth sub-pixel PX4 adjacent to the second sub-pixel PX2, and the partition structure GD between the second sub-pixel PX2 and the fourth sub-pixel PX4, in the direction from the second sub-pixel PX2 to the fourth sub-pixel PX4, the spacing d3 between the first groove 211 and the second sub-pixel PX2 is less than the spacing d4 between the first groove 211 and the fourth sub-pixel PX4.

In the embodiments of the present disclosure, for the fourth sub-pixel PX4, the partition structures GD between the fourth sub-pixel PX4 and other sub-pixels PX are arranged farther away from the fourth sub-pixel PX4, so that a sufficient space may be made for the fourth sub-pixel PX4 to ensure that the effective light-emitting region of the fourth sub-pixel PX4 may have a sufficient area. For example, the third sub-pixels PX3 and the fourth sub-pixels PX4 are alternately arranged in the third direction Z1, and the partition structure GD between the third sub-pixel PX3 and the fourth sub-pixel PX4 is arranged closer to the third sub-pixel PX3. The second sub-pixels PX2 and the fourth sub-pixels PX4 are alternately arranged in the fourth direction Z2, and the partition structure GD between the second sub-pixel PX2 and the fourth sub-pixel PX4 is arranged closer to the second sub-pixel PX2.

Referring to FIG. 9, in some specific embodiments, orthographic projections of partition structures GD adjacent to the third sub-pixel PX3 in the third direction Z1 on the base substrate 200 defines a fourth pattern, which at least partially surrounds the orthographic projection of the pixel opening V1 of the third sub-pixel PX3 on the base substrate 200. Thus, the partition structures GD on opposite sides of the third sub-pixel PX3 fit with the pixel opening V1 of the third sub-pixel PX3, so that a space utilization may be improved.

In some specific embodiments, orthographic projection of partition structures GD adjacent to the second sub-pixel PX2 in the fourth direction Z2 on the base substrate 200 defines a fifth pattern, which at least partially surrounds the orthographic projection of the pixel opening V1 of the second sub-pixel PX2 on the base substrate 200. Thus, the partition structures GD on opposite sides of the second sub-pixel PX2 fit with the pixel opening V1 of the second sub-pixel PX2, so that a space utilization may be improved.

In some specific embodiments, an area of an effective light-emitting region of the first sub-pixel PX1 is greater than that of an effective light-emitting region of the second sub-pixel PX2 and less than that of an effective light-emitting region of the fourth sub-pixel PX4. The area of the effective light-emitting region of the second sub-pixel PX2 is substantially the same as that of an effective light-emitting region of the third sub-pixel PX3.

In the embodiments of the present disclosure, the effective light-emitting region of the sub-pixel PX may refer to the effective light-emitting region of the light-emitting device OL in the sub-pixel PX. The effective light-emitting region of the light-emitting device OL has been described in detail above, and will not be repeated here. For example, the first sub-pixel PX1 may be provided as a red sub-pixel, the second sub-pixel PX2 and the third sub-pixel PX3 may be provided as green sub-pixels, and the fourth sub-pixel PX4 may be provided as a blue sub-pixel. The blue sub-pixel PX has the largest effective light-emitting region, the red sub-pixel PX has an effective light-emitting region smaller than that of the blue sub-pixel PX, and the green sub-pixel PX has the smallest effective light-emitting region.

At least some embodiments of the present disclosure further provide a display panel, which includes the display substrate as described above. The display panel has a display area AA, a peripheral area NA, and related structures therein. For example, the display panel may be an OLED display panel.

At least some embodiments of the present disclosure further provide a display apparatus. The display apparatus may include any apparatus or product having a display function. For example, the display apparatus may be a smart phone, a mobile phone, an e-book reader, a desktop personal computer (PC), a laptop PC, a netbook PC, a personal digital assistant (PDA), a portable multimedia player (PMP), a digital audio player, a mobile medical apparatus, a camera, a wearable device (such as a head-mounted apparatus, electronic clothing, electronic bracelet, electronic necklace, electronic accessory, electronic tattoo, or smart watch), a television, etc.

It will be understood that the display apparatus according to the embodiments of the present disclosure has all the characteristics and advantages of the above-mentioned display substrate and display panel. The details may be referred to the above descriptions and will not be repeated here.

It will be noted that in the above descriptions, the technical solutions of the embodiments of the present disclosure are illustrated by way of example, but it does not mean that the embodiments of the present disclosure are limited to the above-mentioned steps and structures. Where possible, the steps and structures may be adjusted and selected as needed. Therefore, some steps and units are not essential elements for implementing the general inventive concept of the embodiments of the present disclosure.

The present disclosure has been described with reference to preferred embodiments. It should be understood that those skilled in the art may make various other changes, substitutions and additions without departing from the spirit and scope of the embodiments of the present disclosures. Therefore, the scope of the embodiments of the present disclosure is not limited to the aforementioned specific embodiments, but should be defined by the appended claims.

1. A display substrate, comprising:
a base substrate;
a first planarization layer provided on the base substrate;
a first passivation layer provided on a side of the first planarization layer away from the base substrate; and
an organic light-emitting layer and an organic common layer, wherein the organic light-emitting layer and the organic common layer are provided on a side of the first passivation layer away from the base substrate; and,
a plurality of sub-pixels, a partition structure is provided between two sub-pixels adjacent to each other, the partition structure comprises:
a partition portion in the first passivation layer; and
a first groove in the first planarization layer, and an orthographic projection of the partition portion on the base substrate partially overlaps with an orthographic projection of the first groove on the base substrate,
wherein at least one sub-pixel comprises an organic light-emitting device, and the organic light-emitting device comprises a light-emitting portion in the organic light-emitting layer and a charge generation portion in the organic common layer;
wherein for two sub-pixels adjacent to each other and the partition structure between the two sub-pixels adjacent to each other, the charge generation portion of one sub-pixel comprises a first extension sub-portion extending between the two sub-pixels adjacent to each other, and the charge generation portion of the other sub-pixel comprises a second extension sub-portion extending between the two sub-pixels adjacent to each other; and
wherein one of the first extension sub-portion and the second extension sub-portion is on a side of the partition portion away from the base substrate, the other of the first extension sub-portion and the second extension sub-portion is on a bottom wall of the first groove, and the first extension sub-portion and the second extension sub-portion are insulated and spaced apart from each other.

2. The display substrate according to claim 1, wherein the display substrate further comprises a first electrode layer on a side of the organic light-emitting layer proximate to the base substrate, a second electrode layer on a side of the organic light-emitting layer away from the base substrate, and a pixel circuit layer on a side of the first planarization layer proximate to the base substrate;
wherein the at least one sub-pixel further comprises a pixel circuit, the organic light-emitting device further comprises a first electrode in the first electrode layer and a second electrode in the second electrode layer, the first electrode is electrically connected to the pixel circuit, and the second electrode is electrically connected to a first voltage terminal;
wherein for two sub-pixels adjacent to each other and the partition structure between the two sub-pixels adjacent to each other, the second electrode of one sub-pixel comprises a third extension sub-portion extending between the two sub-pixels adjacent to each other, and the second electrode of the other sub-pixel comprises a fourth extension sub-portion extending between the two sub-pixels adjacent to each other; and
wherein the third extension sub-portion is on a side of the first extension sub-portion away from the base substrate, the fourth extension sub-portion is on a side of the second extension sub-portion away from the base substrate, and the third extension sub-portion and the fourth extension sub-portion are insulated and spaced apart from each other.

3. The display substrate according to claim 2, wherein the at least one sub-pixel further comprises a first connecting portion, and in a same sub-pixel, the first electrode is electrically connected to the pixel circuit through the first connecting portion; and
wherein the orthographic projection of the first groove on the base substrate does not overlap with an orthographic projection of the first connecting portion on the base substrate.

4. The display substrate according to claim 1, wherein the partition portion comprises a first partition sub-portion and a second partition sub-portion; and
wherein the first partition sub-portion covers a surface of the first planarization layer on a side away from the base substrate, the orthographic projection of the first groove on the base substrate covers an orthographic projection of the second partition sub-portion on the base substrate, and an orthographic projection of the first partition sub-portion on the base substrate at least partially surrounds the orthographic projection of the second partition sub-portion on the base substrate.

5. The display substrate according to claim 1, wherein for two sub-pixels adjacent to each other and the partition structure between the two sub-pixels adjacent to each other,
in a direction from one sub-pixel to the other sub-pixel, a spacing between the first groove and one sub-pixel is less than a spacing between the first groove and the other sub-pixel,
wherein the first extension sub-portion of the one sub-pixel having a less spacing from the first groove than the other sub-pixel is on the side of the partition portion away from the base substrate, and the second extension sub-portion of the other sub-pixel having a greater spacing from the first groove than the one sub-pixel is on the bottom wall of the first groove.

6. The display substrate according to claim 2, wherein the at least one sub-pixel further comprises a first passivation portion in the first passivation layer, and in a same sub-pixel, an orthographic projection of the first passivation portion on the base substrate covers an orthographic projection of the first electrode on the base substrate; and
wherein for two sub-pixels adjacent to each other and the partition structure between the two sub-pixels adjacent to each other, the first passivation portion of one sub-pixel and the partition portion are formed as an integral structure.

7. The display substrate according to claim 6, wherein the display substrate further comprises a first pixel defining layer on a side of the first electrode layer away from the base substrate and a second pixel defining layer between the first pixel defining layer and the first passivation layer, a material of the first pixel defining layer comprises a black pixel defining material, and a material of the second pixel defining layer comprises a transparent pixel defining material;
wherein the at least one sub-pixel further comprises a pixel defining portion in the first pixel defining layer and an auxiliary attaching portion in the second pixel defining layer; and
wherein in a same sub-pixel, the pixel defining portion is configured to define an effective light-emitting region of the organic light-emitting device, the pixel defining portion is attached to the first passivation portion through the auxiliary attaching portion, and a maximum thickness of the auxiliary attaching portion is less than or equal to a maximum thickness of the pixel defining portion.

8. The display substrate according to claim 7, wherein in a same sub-pixel, an orthographic projection of the pixel defining portion on the base substrate overlaps with the orthographic projection of the first passivation portion on the base substrate, and an overlap between the orthographic projection of the pixel defining portion on the base substrate and the orthographic projection of the first passivation portion on the base substrate defines a first pattern; and
wherein the first pattern comprises a middle region and an edge region outside the middle region, the orthographic projection of the first electrode on the base substrate covers the middle region, and an orthographic projection of the auxiliary attaching portion on the base substrate covers the edge region.

9. The display substrate according to claim 7, wherein in a same sub-pixel, an orthographic projection of the auxiliary attaching portion on the base substrate surrounds the orthographic projection of the first electrode on the base substrate.

10. The display substrate according to claim 2, wherein for two sub-pixels adjacent to each other and the partition structure between the two sub-pixels adjacent to each other, an orthographic projection of the first electrode of at least one sub-pixel on the base substrate does not overlap with the orthographic projection of the partition portion on the base substrate.

11. The display substrate according to claim 1, wherein a plurality of partition structures are provided between two sub-pixels adjacent to each other, and at least two of the plurality of partition structures have different areas.

12. The display substrate according to claim 6, wherein the display substrate further comprises a second planarization layer between the first passivation layer and the first electrode layer;
wherein the at least one sub-pixel further comprises a first spacing portion in the second planarization layer; and
wherein in a same sub-pixel, the orthographic projection of the first electrode on the base substrate overlaps with the orthographic projection of the first passivation portion on the base substrate, an overlap between the orthographic projection of the first electrode on the base substrate and the orthographic projection of the first passivation portion on the base substrate defines a second pattern, and an orthographic projection of the first spacing portion on the base substrate covers the second pattern.

13. The display substrate according to claim 12, wherein in a same sub-pixel, an orthographic projection of the pixel defining portion on the base substrate overlaps with the orthographic projection of the first passivation portion on the base substrate, an overlap between the orthographic projection of the pixel defining portion on the base substrate and the orthographic projection of the first passivation portion on the base substrate defines a first pattern, and the orthographic projection of the first spacing portion on the base substrate covers the first pattern.

14. The display substrate according to claim 13, wherein the at least one sub-pixel further comprises a first planarization portion in the first planarization layer; and
wherein in a same sub-pixel, a thickness of the first spacing portion is less than or equal to a thickness of the first passivation portion, and the thickness of the first passivation portion is less than a thickness of the first planarization portion.

15. The display substrate according to claim 1, wherein the plurality of sub-pixels comprise a first sub-pixel, a second sub-pixel, and a third sub-pixel, the first sub-pixel and the second sub-pixel have different colors, and the second sub-pixel has the same color as the third sub-pixel;
wherein for a first sub-pixel, a second sub-pixel adjacent to the first sub-pixel, and the partition structure between the first sub-pixel and the second sub-pixel, in a direction from the first sub-pixel to the second sub-pixel, a spacing between the first groove and the first sub-pixel is less than a spacing between the first groove and the second sub-pixel; and
wherein for a first sub-pixel, a third sub-pixel adjacent to the first sub-pixel, and the partition structure between the first sub-pixel and the third sub-pixel, in a direction from the first sub-pixel to the third sub-pixel, a spacing between the first groove and the first sub-pixel is less than a spacing between the first groove and the third sub-pixel.

16. The display substrate according to claim 15, wherein the orthographic projection of the partition structure adjacent to the first sub-pixel on the base substrate defines a third pattern at least partially surrounding an orthographic projection of a pixel opening of the first sub-pixel on the base substrate;
wherein the orthographic projection of the partition structure adjacent to the third sub-pixel in the third direction on the base substrate defines a fourth pattern at least partially surrounding an orthographic projection of a pixel opening of the third sub-pixel on the base substrate; and/or
wherein the orthographic projection of the partition structure adjacent to the second sub-pixel in the fourth direction on the base substrate defines a fifth pattern at least partially surrounding an orthographic projection of a pixel opening of the second sub-pixel on the base substrate.

17. The display substrate according to claim 15, wherein the plurality of sub-pixels further comprise a fourth sub-pixel, and the first sub-pixel, the second sub-pixel and the fourth sub-pixel have different colors from each other;
wherein for a third sub-pixel, a fourth sub-pixel adjacent to the third sub-pixel, and the partition structure between the third sub-pixel and the fourth sub-pixel, in a direction from the third sub-pixel to the fourth sub-pixel, a spacing between the first groove and the third sub-pixel is less than a spacing between the first groove and the fourth sub-pixel; and
wherein for a second sub-pixel, a fourth sub-pixel adjacent to the second sub-pixel, and the partition structure between the second sub-pixel and the fourth sub-pixel, in a direction from the second sub-pixel to the fourth sub-pixel, a spacing between the first groove and the second sub-pixel is less than a spacing between the first groove and the fourth sub-pixel.

18. The display substrate according to claim 16, wherein an area of an effective light-emitting region of the first sub-pixel is greater than an area of an effective light-emitting region of the second sub-pixel and is less than an area of an effective light-emitting region of the fourth sub-pixel, and the area of the effective light-emitting region of the second sub-pixel is substantially equal to the area of the effective light-emitting region of the third sub-pixel;
wherein the display substrate further comprises a plurality of gate lines extending in a first direction and a plurality of data lines extending in a second direction;
wherein first sub-pixels and second sub-pixels are alternately arranged in a third direction, the first sub-pixels and third sub-pixels are alternately arranged in a fourth direction, the third sub-pixels and fourth sub-pixels are alternately arranged in the third direction, and the second sub-pixels and the fourth sub-pixels are alternately arranged in the fourth direction; and
wherein the first direction, the second direction, the third direction and the fourth direction intersect with one another.

19. (canceled)

20. (canceled)

21. A display panel, comprising the display substrate according to claim 1.

22. A display apparatus, comprising the display panel according to claim 21.
